(19) United States
(12) Patent Application Publication
(10) Pub. No.: US 2026/0292359 A1
(43) Pub. Date: Sep. 24, 2026

(54) IMAGE SENSING DEVICE AND IMAGING DEVICE INCLUDING THE SAME

(71) Applicant: SK hynix Inc., Gyeonggi-do (KR)

(72) Inventor: Yuta SUZUKI, Tokyo (JP)

(21) Appl. No.: 19/367,736

(22) Filed: Oct. 23, 2025

(30) Foreign Application Priority Data
Mar. 24, 2025 (KR) 10-2025-0037146

(51) Int. Cl. H04N 25/46; H04N 25/40; H04N 25/585; H04N 25/13

(52) U.S. Cl. CPC H04N 25/46; H04N 25/41; H04N 25/585; H04N 25/134

(57) ABSTRACT

An image sensing device includes a pixel group including a plurality of first pixels having a first photosensitivity and at least one second pixel having a second photosensitivity, and a binning circuit configured to generate a first binning image by binning some first pixels among the plurality of first pixels, generate a second binning image by binning the plurality of first pixels, and generate a third binning image by binning the at least one second pixel.

### CROSS-REFERENCE TO RELATED APPLICATION

This patent application claims the priority and benefits of Korean patent application No. 10-2025-0037146, filed on Mar. 24, 2025, the disclosure of which is incorporated by reference in its entirety.

### TECHNICAL FIELD

The technology and embodiments of the present disclosure generally relate to an image sensing device capable of generating parallax images.

### BACKGROUND

In general, Complementary Metal Oxide Semiconductor (CMOS) image sensing devices, which are implemented using the CMOS process, are devices that capture optical images using the properties of photosensitive semiconductor materials that react to light. With the development of automotive, medical, computer and communication industries, the demand for high-performance image sensing devices is increasing in various fields such as smartphones, digital cameras, game machines, Internet of Things (IoT), robots, security cameras and medical micro cameras.

For a device (e.g., a camera) for photographing a target object, it is important to accurately focus on the target object to capture a clear image (e.g., a still image) or video (e.g., moving image).

### SUMMARY

Various embodiments of the present disclosure relate to an image sensing device capable of reducing the amount of parallax between a high-sensitivity image and a low-sensitivity image for use in an image sensor including high-sensitivity pixels and low-sensitivity pixels to generate a high dynamic range (HDR) image.

In accordance with an embodiment of the present disclosure, an image sensing device may include a pixel group including a plurality of first pixels having a first photosensitivity and at least one second pixel having a second photosensitivity; and a binning circuit configured to generate a first binning image by binning some first pixels among the plurality of first pixels; generate a second binning image by binning the plurality of first pixels; and generate a third binning image by binning the at least one second pixel.

In accordance with another embodiment of the present disclosure, an image sensing device may include a first pixel; a second pixel arranged adjacent to the first pixel in a first direction; a third pixel arranged adjacent to the first pixel in a second direction; a fourth pixel arranged adjacent to the third pixel in the first direction; and a binning circuit configured to generate a first binning image by binning the first pixel and the third pixel; generate a second binning image by binning the first pixel, the second pixel, and the third pixel; and generate a third binning image by reading a pixel signal of the fourth pixel.

In accordance with another embodiment of the present disclosure, an image sensing device may include a plurality of pixel blocks including a plurality of pixel groups arranged in a Bayer pattern, and arranged in a first direction and a second direction perpendicular to the first direction; and a binning circuit configured to bin pixels included in each of the plurality of pixel groups. Each of the plurality of pixel groups includes a plurality of first pixels each having a first sensitivity and a plurality of second pixels each having a second sensitivity different from the first sensitivity. The pixel blocks adjacent to each other in the first direction and the second direction are configured such that the first pixels and the second pixels are arranged in different patterns. The binning circuit outputs a first binning image by binning pixels disposed in one column line or one row line among the plurality of first pixels, outputs a second binning image by binning the plurality of first pixels, and outputs a third binning image by binning the second pixels.

In accordance with another embodiment of the present disclosure, an image sensing device may include a first pixel block including a plurality of first pixel groups arranged in a Bayer pattern; a second pixel block located adjacent to the first pixel block in a first direction and including a plurality of second pixel groups arranged in a Bayer pattern; and a binning circuit configured to generate binning images by binning pixels of the first pixel block and the second pixel block. Each of the plurality of first pixel groups includes a plurality of first pixels having a first photosensitivity and a second pixel having a second photosensitivity. Each of the plurality of second pixel groups includes a plurality of third pixels having the first photosensitivity and a fourth pixel having the second photosensitivity. The plurality of first pixels and the plurality of third pixels are arranged symmetrically to each other in a specific direction. The second pixel and the fourth pixel are arranged symmetrically to each other in the specific direction.

In accordance with another embodiment of the present disclosure, an imaging device may include an image sensing device including a plurality of first pixels having a first photosensitivity and at least one second pixel having a second photosensitivity, and configured to generate parallax images for a specific direction in response to binning images obtained by binning the plurality of first pixels and the at least one second pixel; and a parallax calculator configured to compare the parallax images with each other to calculate parallax for the specific direction. The image sensing device is configured to generate a first binning image by binning some first pixels among the plurality of first pixels; generate a second binning image by binning the plurality of first pixels; and generate a third binning image by binning the at least one second pixel.

It is to be understood that both the foregoing general description and the following detailed description of the present disclosure are illustrative and descriptive and are intended to provide further description of the embodiments of the present disclosure as claimed.

### BRIEF DESCRIPTION OF THE DRAWINGS

The above and other features and beneficial aspects of the embodiments of the present disclosure will become readily apparent with reference to the following detailed description when considered in conjunction with the accompanying drawings.

FIG. 1 is a block diagram illustrating an imaging device based on some embodiments of the present disclosure.

FIG. 2 is a block diagram illustrating the image sensing device show in FIG. 1 based on some embodiments of the present disclosure.

FIG. 3 is a diagram illustrating a structure of a pixel block in the pixel array shown in FIG. 2 based on some embodiments of the present disclosure.

FIG. 4 is a diagram illustrating a structure in which pixel blocks are consecutively arranged in the pixel array shown in FIG. 2 based on some embodiments of the present disclosure.

FIG. 5 is a diagram illustrating a case in which a length of a center-line between pixels is not adjusted according to an arrangement pattern of the pixels within a pixel group based on some embodiments of the present disclosure.

FIGS. 6A to 6D are diagrams illustrating a first embodiment of generating horizontal parallax images and calculating a horizontal parallax in the pixel array structure of FIG. 4 based on some embodiments of the present disclosure.

FIGS. 7A to 7D are diagrams illustrating a second embodiment of generating vertical parallax images and calculating a vertical parallax in the pixel array structure of FIG. 4 based on some embodiments of the present disclosure.

FIG. 8 is a diagram illustrating another embodiment of a structure of a pixel block in the pixel array of FIG. 2 based on some embodiments of the present disclosure.

FIG. 9 is a diagram illustrating another embodiment of a structure in which pixel blocks are consecutively arranged in the pixel array of FIG. 2 based on some embodiments of the present disclosure.

FIGS. 10A to 10C are diagrams illustrating a third embodiment of generating horizontal parallax images and calculating horizontal parallax in the pixel array structure of FIG. 9 based on some embodiments of the present disclosure.

FIGS. 11A to 11C are diagrams illustrating a fourth embodiment of generating vertical parallax images and calculating a vertical parallax in the pixel array structure of FIG. 9 based on some embodiments of the present disclosure.

FIG. 12 is a diagram illustrating another embodiment of a structure in which pixel blocks are consecutively arranged in the pixel array of FIG. 2 based on some embodiments of the present disclosure.

FIGS. 13A to 13C are diagrams illustrating a fifth embodiment of generating horizontal parallax images and calculating a horizontal parallax in the pixel array structure of FIG. 12 based on some embodiments of the present disclosure.

FIG. 14 is a diagram illustrating another embodiment of a structure in which pixel blocks are consecutively arranged in the pixel array of FIG. 2 based on some embodiments of the present disclosure.

FIGS. 15A to 15C are diagrams showing a sixth embodiment of generating vertical parallax images and calculating a vertical parallax in the pixel array structure of FIG. 14 based on some embodiments of the present disclosure.

### DETAILED DESCRIPTION

The present disclosure provides embodiments and examples of an image sensing device capable of generating parallax images that may be used in configurations to substantially address one or more technical or engineering issues and to mitigate limitations or disadvantages encountered in some imaging devices in the art. Some embodiments of the present disclosure relate to an image sensing device that can reduce the amount of parallax between a high-sensitivity image and a low-sensitivity image for use in an image sensor including high-sensitivity pixels and low-sensitivity pixels, to generate a high dynamic range (HDR) image. In recognition of the issues above, the image sensing device according to the embodiments of the present disclosure can improve autofocus accuracy by reducing the amount of parallax between the high-sensitivity image and the low-sensitivity image.

Reference will now be made in detail to some embodiments of the present disclosure, examples of which are illustrated in the accompanying drawings. Wherever possible, the same reference numbers will be used throughout the drawings to refer to the same or like parts. While the embodiments are susceptible to various modifications and alternative forms, specific embodiments thereof are shown in the drawings. However, the embodiments should not be construed as being limited to the embodiments set forth herein.

Hereinafter, various embodiments will be described with reference to the accompanying drawings. However, it should be understood that the embodiments of the present disclosure are not limited to specific embodiments, but includes various modifications, equivalents and/or alternatives of the embodiments. The embodiments of the present disclosure may provide a variety of advantageous effects capable of being directly or indirectly recognized by one of ordinary skill in the art.

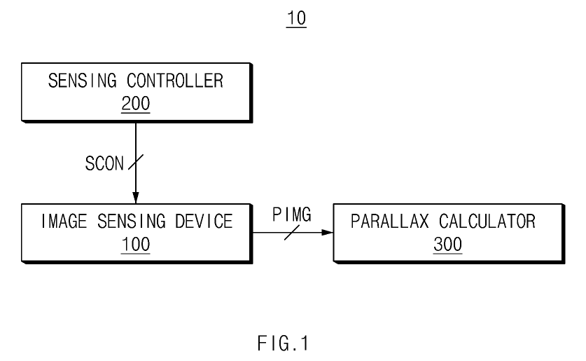

FIG. 1 is a block diagram illustrating an imaging device 10 based on some embodiments of the present disclosure.

Referring to FIG. 1, the imaging device 10 may include an image sensing device 100, a sensing controller 200, and a parallax calculator 300.

Here, the image sensing device 100 may capture a subject and convert an optical signal for the captured subject into an electrical signal to generate a parallax image (PIMG). For example, the image sensing device 100 may include a plurality of pixels that capture a subject and convert an optical signal obtained by capturing the subject into an electrical signal (pixel signal), and may convert pixel signals output from the plurality of pixels into digital signals using an analog-to-digital converter (ADC) to generate a parallax image (PIMG).

The plurality of pixels may include high-sensitivity pixels and low-sensitivity pixels for high dynamic range (HDR) imaging. The high-sensitivity pixels and the low-sensitivity pixels may have sensing conditions changed based on a control signal (SCON) of the sensing controller 200. A signal generated by some of the high-sensitivity pixels or the low-sensitivity pixels may be used as a signal for autofocus.

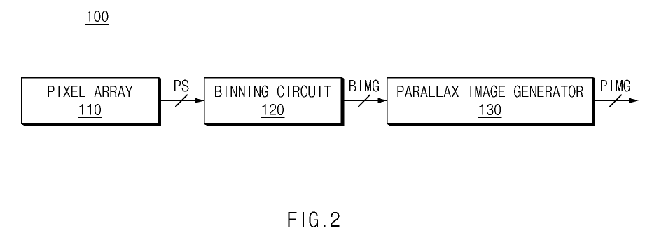

For example, the image sensing device 100 may generate parallax images (PIMG) for autofocus. The parallax images (PIMG) may include a high-sensitivity parallax image generated using signals from some of the high-sensitivity pixels or a low-sensitivity parallax image generated using pixel signals from some (or all) of the low-sensitivity pixels. The configuration and operation of the image sensing device 100 will be described in more detail later with reference to FIG. 2.

In addition, the sensing controller 200 may generate a control signal (SCON) according to a preset logic. The sensing controller 200 may control at least one of an exposure time, a conversion gain, and an analog gain of the image sensing device 100 based on the control signal (SCON). For example, the sensing controller 200 may include position information (i.e., position information within the pixel array) for preset high-sensitivity pixels and preset low-sensitivity pixels. The sensing controller 200 may control at least one of the exposure time, conversion gain, and analog gain of the high-sensitivity pixels and the low-sensitivity pixels based on the position information to allow the image sensing device 100 to generate an HDR (High Dynamic Range) image.

The parallax calculator 300 may calculate a horizontal parallax (i.e., a first-directional parallax) or a vertical parallax (i.e., a second-directional parallax) for the image sensing device 100 using the parallax images (PIMG) received from the image sensing device 100. Here, the parallax calculator 300 may calculate the horizontal parallax or the vertical parallax by comparing high-sensitivity parallax images with each other or by comparing low-sensitivity parallax images with each other.

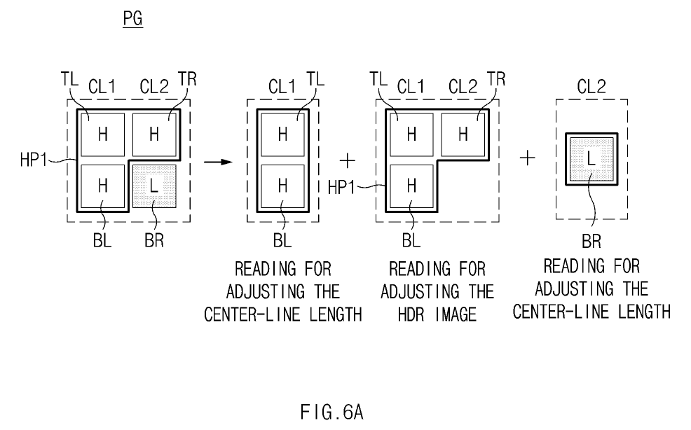

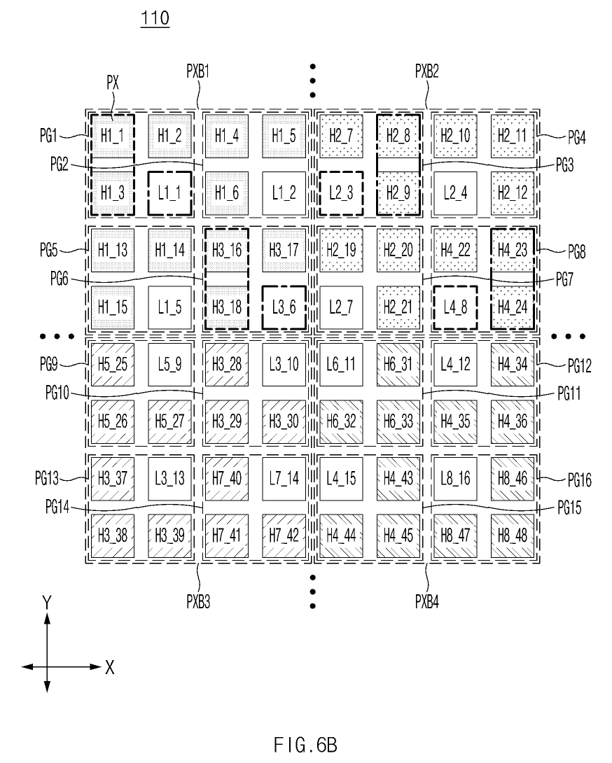

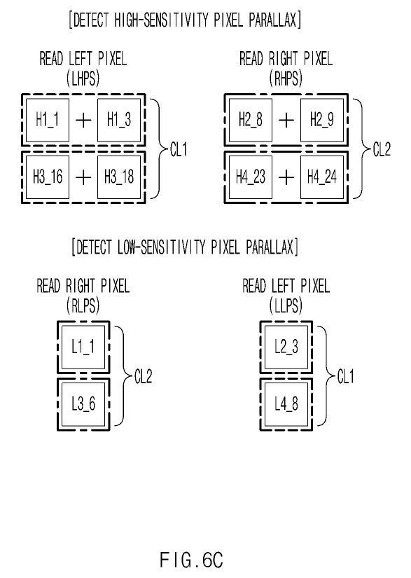

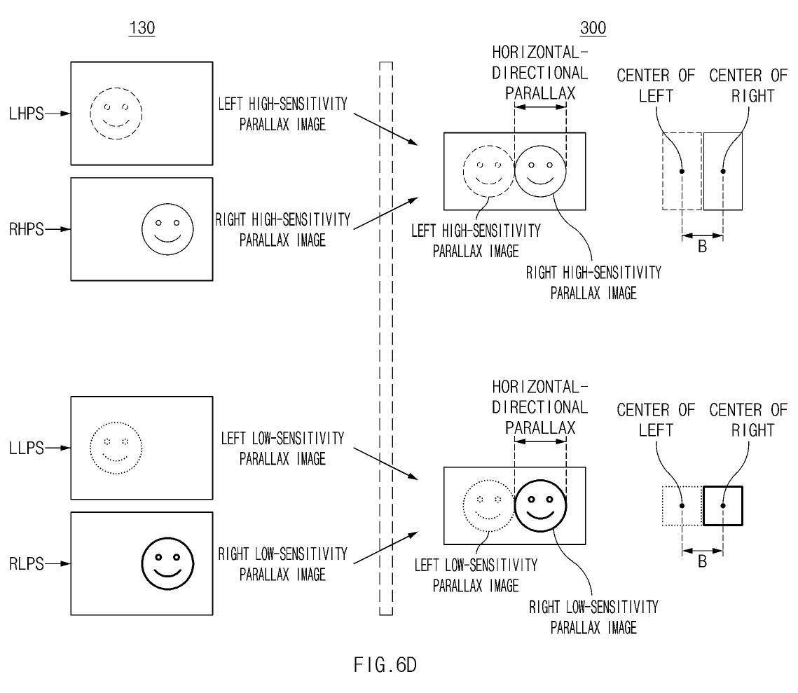

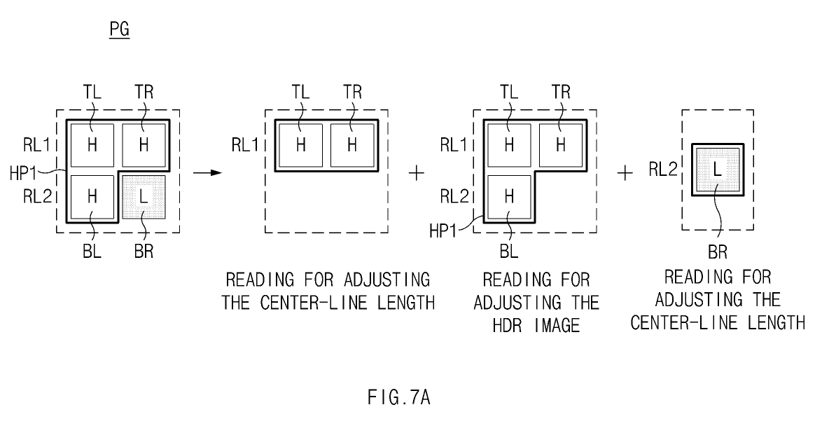

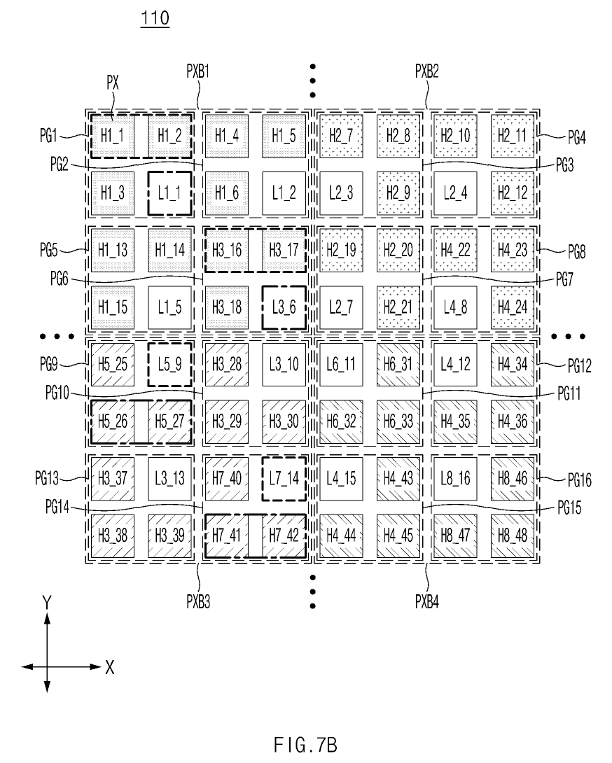

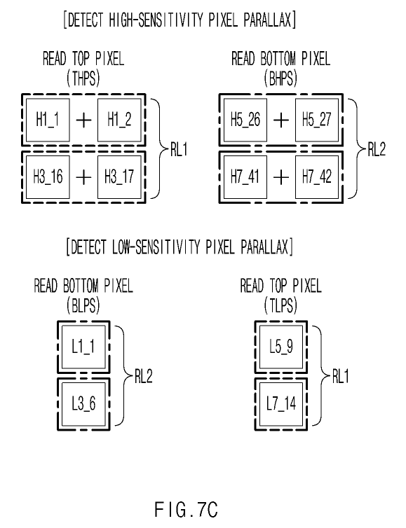

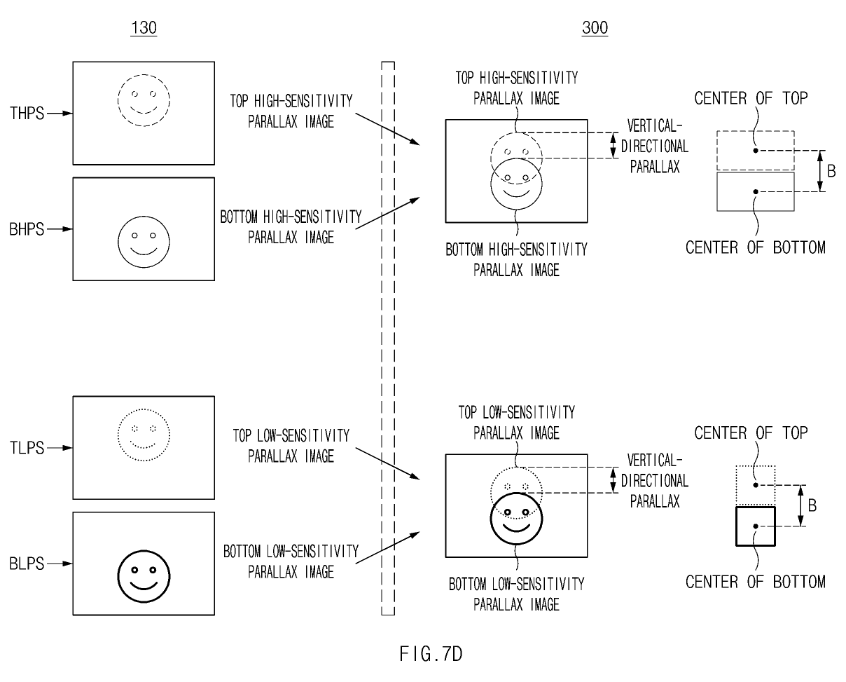

For example, the parallax calculator 300 may calculate the horizontal parallax by comparing at least two high-sensitivity parallax images (e.g., a left high-sensitivity parallax image and a right high-sensitivity parallax image) in the horizontal direction with each other. The parallax calculator 300 may calculate the horizontal parallax by comparing at least two low-sensitivity parallax images (e.g., a left low-sensitivity parallax image and a right low-sensitivity parallax image) in the horizontal direction with each other. Alternatively, the parallax calculator 300 may calculate the vertical parallax by comparing at least two high-sensitivity parallax images (e.g., a top high-sensitivity parallax image and a bottom high-sensitivity parallax image) in the vertical direction with each other. The parallax calculator 300 may calculate the vertical parallax by comparing at least two low-sensitivity parallax images (e.g., a top low-sensitivity parallax image and a bottom low-sensitivity parallax image) in the vertical direction with each other. The configuration and operation of the parallax calculator 300 will be described in more detail with reference to FIGS. 6D and 7D to be described below.

FIG. 2 is a block diagram illustrating the image sensing device 100 shown in FIG. 1 based on some embodiments of the present disclosure.

Referring to FIG. 2, the image sensing device 100 may include a pixel array 110, a binning circuit 120, and a parallax image generator 130. The constituent components of the image sensing device 100 illustrated in FIG. 1 are discussed by way of example only, and the embodiment may encompass numerous other changes, substitutions, variations, alterations, and modifications. In the present disclosure, the word “pixel” can be used to indicate an image sensing pixel that is structured to detect incident light to generate electrical signals carrying images in the incident light.

The pixel array 110 may include a plurality of pixels arranged in a plurality of rows and a plurality of columns. In one embodiment, the plurality of pixels may be arranged in a two-dimensional (2D) pixel array including rows and columns. In another embodiment, the plurality of pixels may be arranged in a three-dimensional (3D) pixel array. The plurality of pixels may be grouped into pixel groups.

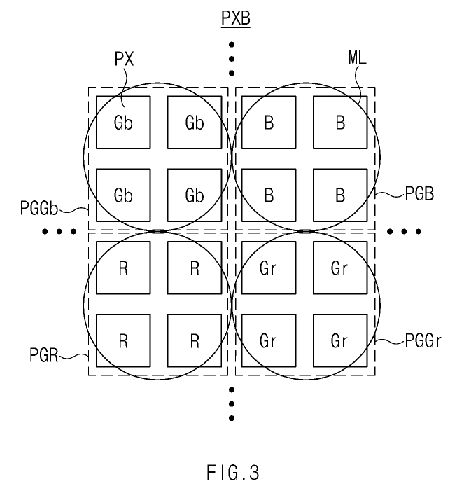

The plurality of pixels may convert an optical signal into an electrical signal either on a pixel basis or a pixel group basis, and may output a pixel signal (PS). For example, the pixel array 110 may include high-sensitivity pixels and low-sensitivity pixels. The pixel signal (PS) may include a high-sensitivity pixel signal detected by the high-sensitivity pixels and a low-sensitivity pixel signal detected by the low-sensitivity pixels. The detailed configuration of the pixel array 110 will be described in more detail later with reference to FIGS. 3, 4, 8, 9, 12, and 14.

The binning circuit 120 may perform binning of the pixel signal (PS) received from the pixel array 110, may convert the binned pixel signal into a digital signal, and may generate binning images (BIMG). Here, the term “binning” may refer to a process of compressing data by discarding some of the data acquired through the entire pixels or summing some of the data acquired through the entire pixels and other data, when the resolution of a required image can be implemented with only some of the entire pixels of the image sensor. As another example, in the case of a single pixel, 'binning' might mean acquiring data for at least one pixel.

In some embodiments, the binning circuit 120 may generate binning images (BIMG) by summing the pixel signal (PS) received from the pixel array 110 and converting the summed pixel signal (PS) into a digital signal. Here, the term “summing” may refer to a process of summing (or averaging) the pixel values (or pixel signals) of the pixels.

In the present disclosure, the binning circuit 120 will be described as an example of binning the pixel signal (PS) for convenience of description and better understanding of the present disclosure. For example, the binning circuit 120 may generate a first high-sensitivity binning image by binning at least two high-sensitivity pixel signals. The binning circuit 120 may generate a second high-sensitivity binning image by binning at least three high-sensitivity pixel signals to generate an HDR image. The binning circuit 120 may generate a low-sensitivity binning image by binning at least one low-sensitivity pixel signal. Here, the first high-sensitivity binning image, the second high-sensitivity binning image, and the low-sensitivity binning image may correspond to the binning images (BIMG) described above. The operation of the binning circuit 120 will be described in more detail with reference to FIGS. 6A to 6C, 7A to 7C, 10A to 10C, 11A to 11C, 13A to 13C, and 15A to 15C to be described below.

The parallax image generator 130 may generate parallax images (PIMG) by aligning phases of the binning images (BIMG). Here, the parallax images (PIMG) may include high-sensitivity parallax images and low-sensitivity parallax images.

For example, the parallax image generator 130 may generate at least two high-sensitivity parallax images (e.g., a left high-sensitivity parallax image and a right high-sensitivity parallax image) in the horizontal direction. The parallax image generator 130 may generate at least two low-sensitivity parallax images (e.g., a left low-sensitivity parallax image and a right low-sensitivity parallax image) in the horizontal direction. Alternatively, the parallax image generator 130 may generate at least two high-sensitivity parallax images (e.g., a top high-sensitivity parallax image and a bottom high-sensitivity parallax image) in the vertical direction. The parallax image generator 130 may generate at least two low-sensitivity parallax images (e.g., a top low-sensitivity parallax image and a bottom low-sensitivity parallax image) in the vertical direction. The operation of the parallax image generator 130 will be described in more detail with reference to FIGS. 6D and 7D to be described below.

FIG. 3 is a diagram illustrating a structure of a pixel block in the pixel array 110 shown in FIG. 2 based on some embodiments of the present disclosure.

Referring to FIG. 3, the pixel array 110 may include a plurality of pixel blocks (PXBs). Each pixel block (PXB) may include a plurality of pixel groups (PGR, PGGb, PGGr, PGB) arranged adjacent to each other. Each pixel group (PGR, PGGb, PGGr, PGB) may share one microlens (ML), and may include a plurality of pixels (PXs) having a color filter of the same color.

The pixels (PXs) of each pixel group (PGR, PGGb, PGGr, PGB) may be arranged adjacent to each other in an (M × N) matrix structure, where “M” and “N” are integers greater than or equal to 2 and may be the same or different from each other. For example, the pixel group (PGR) may include four red-color (R) pixels (PXs) arranged in a (2 × 2) matrix structure while sharing one microlens (ML).

Each of the pixel groups (PGGr, PGGb) may include four pixels (PXs) of green-color (Gr, Gb) arranged in a (2 × 2) matrix structure while sharing one microlens (ML). In more detail, the pixel group (PGGr) may include four green-color (Gr) pixels arranged in a (2 × 2) matrix structure while sharing one microlens (ML), and the pixel group (PGGb) may include four green-color (Gb) pixels arranged in a (2 × 2) matrix structure while sharing one microlens (ML). The pixel group (PGB) may include four blue-color (B) pixels (PX) arranged in a (2 × 2) matrix structure while sharing one microlens (ML). For example, the pixel groups (PGR, PGGr, PGGb, PGB) may be arranged in a Bayer pattern.

Each pixel (PX) may include a photosensitive element that converts incident light into an electrical signal corresponding to the incident light. For example, the photosensitive element may be implemented as a photodiode, a phototransistor, a photogate, a pinned photodiode, or a combination thereof.

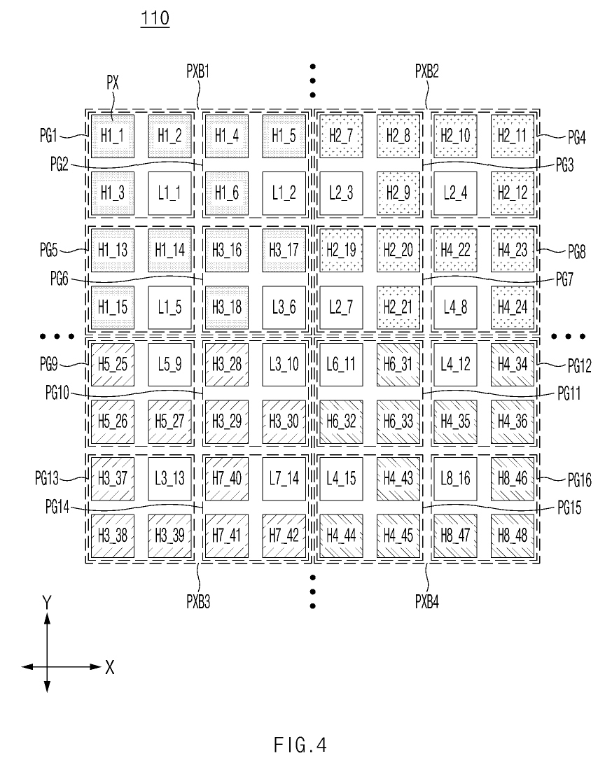

FIG. 4 is a diagram illustrating a structure in which pixel blocks are consecutively arranged in the pixel array 110 shown in FIG. 2 based on some embodiments of the present disclosure.

Referring to FIG. 4, the pixel array 110 may include a plurality of pixel blocks (PXB1~PXB4) arranged adjacent to each other in a first direction (e.g., an X-axis direction) and a second direction (e.g., a Y-axis direction). The pixel blocks (PXB1~PXB4) may include a plurality of pixel groups (PG1~PG16) arranged adjacent to each other. In more detail, the pixel block (PXB1) may include the plurality of pixel groups (PG1, PG2, PG5, PG6), the pixel block (PXB2) may include the plurality of pixel groups (PG3, PG4, PG7, PG8), the pixel block (PXB3) may include the plurality of pixel groups (PG9, PG10, PG13, PG14), and the pixel block (PXB4) may include the plurality of pixel groups (PG11, PG12, PG15, PG16).

Each of the pixel groups (PG1, PG3, PG6, PG8, PG9, PG11, PG14, PG16) may include four green-color (G) pixels (PX). Each of the pixel groups (PG2, PG4, PG10, PG12) may include four blue-color (B) pixels (PX). Each of the pixel groups (PG5, PG7, PG13, PG15) may include four red-color (R) pixels (PX). In addition to the pixel groups described above, it may be understood that the remaining pixel groups of the pixel array 110 are also arranged in the same pattern.

The plurality of pixel groups (PG1~PG16) may include high-sensitivity pixels (H1_1~H8_48) and low-sensitivity pixels (L1_1~L8_16) for generating an HDR image. For example, the pixels (PXs) included in each pixel group (PG1~PG16) may correspond to either a high-sensitivity pixel or a low-sensitivity pixel. In the pixels (PXs) shown in FIG. 4, some pixels (PXs) denoted by “H” may correspond to high-sensitivity pixels. In the pixels (PXs) shown in FIG. 4, some pixels (PXs) denoted by “L” may correspond to low-sensitivity pixels.

Each of the high-sensitivity pixels (H1_1~H8_48) may refer to a pixel having a relatively large increase in response due to an increase in the intensity of incident light. Here, the response may refer to a pixel signal (PS) generated by the high-sensitivity pixels (H1_1~H8_48) detecting the intensity of incident light. Each of the high-sensitivity pixels (H1_1~H8_48) may refer to a pixel having a relatively high photosensitivity to incident light.

Each of the low-sensitivity pixels (L1_1~L8_16) may refer to a pixel having a relatively small increase in response due to an increase in the intensity of incident light. Each of the low-sensitivity pixels (L1_1~L8_16) may refer to a pixel having a relatively low photosensitivity to incident light.

The high-sensitivity pixels or low-sensitivity pixels of the pixel blocks (PXB~PXB4) may be used to generate parallax images in a first direction (e.g., a horizontal direction). The high-sensitivity pixels or low-sensitivity pixels of the pixel blocks (PXB1~PXB4) may be used to generate parallax images in a second direction (e.g., a vertical direction).

In some embodiments, each pixel group (PG1~PG16) of the pixel blocks (PXB1~PXB4) may include three high-sensitivity pixels and one low-sensitivity pixel. The arrangement patterns of the high-sensitivity pixels and the low-sensitivity pixels between the pixel blocks (PXB1~PXB4) adjacent to each other in the first direction may be symmetrical to each other in the first direction. In addition, the arrangement patterns of the high-sensitivity pixels and the low-sensitivity pixels between the pixel blocks (PXB1~PXB4) adjacent to each other in the second direction may be symmetrical to each other in the second direction.

For example, high-sensitivity pixels (H1_1~H1_3, H1_4~H1_6, H1_13~H1_15, H3_16~H3_18) in the pixel groups (PG1, PG2, PG5, PG6) of the pixel block (PXB1) may have an arrangement pattern formed in the shape of “┌”. High-sensitivity pixels (H2_7~H2_9, H2_10~H2_12, H2_19~H2_21, H4_22~H4_24) in the pixel groups (PG3, PG4, PG7, PG8) of the pixel block (PXB2) adjacent to the pixel block (PXB1) in the first direction may have an arrangement pattern formed in the shape of “┐”.

High-sensitivity pixels (H5_25~H5_27, H3_28~H3_30, H3_37~H3_39, H7_40~H7_42) in the pixel groups (PG9, PG10, PG13, PG14) of the pixel block (PXB3) adjacent to the pixel block (PXB1) in the second direction may have an arrangement pattern formed in the shape of “L”. High-sensitivity pixels (H6_31~H6_33, H4_34~H4_36, H4_43~H4_45, H8_46~H8_48) in the pixel groups (PG11, PG12, PG15, PG16) of the pixel block (PXB4) adjacent to the pixel block (PXB3) in the first direction may have an arrangement pattern formed in the shape of “┘”.

The pixel array 110 according to the present embodiment may include pixels (PX) having different photosensitivities for HDR implementation. The pixels (PXs) having the same photosensitivity may be arranged symmetrically to each other in adjacent pixel blocks (PXB1~PXB4) to implement autofocus. At this time, the arrangement patterns being symmetrical to each other in the first direction may mean that the centers of the corresponding arrangement patterns are located on the same line in the first direction, and the arrangement patterns being symmetrical to each other in the second direction may mean that the centers of the corresponding arrangement patterns are located on the same line in the second direction.

The pixel blocks (PXB1~PXB4) arranged as in FIG. 4 may be formed in various positions within the pixel array 110, and the number of pixel blocks (PXB1~PXB4) is not limited thereto. In addition, the positions of the high-sensitivity pixels and the positions of the low-sensitivity pixels may be interchanged in the arrangement structure of FIG. 4. For example, the low-sensitivity pixels may be formed at the positions of the high-sensitivity pixels shown in FIG. 4, and the high-sensitivity pixels may be formed at the positions of the low-sensitivity pixels shown in FIG. 4.

In addition, the arrangement pattern of the high-sensitivity pixels in the pixel blocks (PXB1~PXB4) may be changed to a different shape within a range within which the arrangement patterns of the high-sensitivity pixels of the pixel blocks (PXB1~PXB4) are symmetrical to each other in the first direction and the second direction. For example, the arrangement pattern of the high-sensitivity pixels may be formed in a “┘”-shape within the pixel block (PXB1), the arrangement pattern of the high-sensitivity pixels may be formed in a “L”-shape within the pixel block (PXB2), the arrangement pattern of the high-sensitivity pixels may be formed in a “┐”-shape within the pixel block (PXB3), and the arrangement pattern of the high-sensitivity pixels may be formed in a “┌”-shape within the pixel block (PXB4).

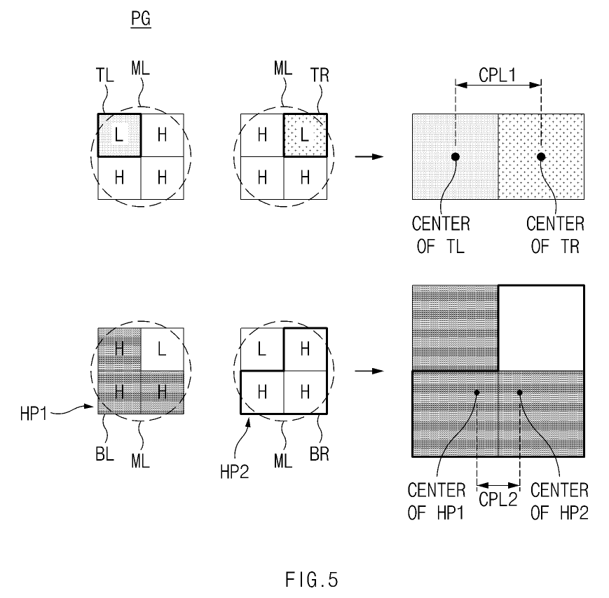

FIG. 5 is a diagram illustrating a case in which the length of a center-line between pixels is not adjusted according to the arrangement pattern of the pixels within a pixel group (PG) based on some embodiments of the present disclosure. In FIG. 5, the pixel group (PG) including four green-color (G) pixels arranged in a (2 × 2) matrix structure will be described.

The image sensing device 100 may include a phase-difference detection autofocus (PDAF) function that automatically focuses by detecting a phase difference between adjacent pixels. The phase difference detection autofocus method is a method of measuring an offset direction and an offset amount from a center image obtained through the image sensing device 100 using a phase difference between two or more different distance measurement points. In addition, to improve the PDAF function, a structure in which a plurality of pixels of the same color is arranged adjacent to each other and one microlens (ML) is applied to the plurality of e pixels is used in the image sensing device 100.

For example, among the four green-color (G) pixels of the pixel group (PG), “TL” may represent a pixel located at a top-left position, “TR” may represent a pixel located at a top-right position, “BL” may represent a pixel located at a bottom-left position, and “BR” may represent a pixel located at a bottom-right position. The TL pixel and the TR pixel may be adjacent to each other in the first direction (i.e., the horizontal direction). The BL pixel and the BR pixel may be adjacent to each other in the first direction (i.e., the horizontal direction). The TL pixel and the BL pixel may be adjacent to each other in the second direction (i.e., the vertical direction). The TR pixel and the BR pixel may be adjacent to each other in the second direction (i.e., the vertical direction). Four pixels (TL, TR, BL, BR) included in one pixel group (PG) may share one microlens (ML).

However, the image sensing device having a structure in which a single microlens (ML) is applied to multiple pixels may have difficulty in accurately performing autofocus due to differences in parallax caused by factors such as astigmatism of a lens. In particular, the parallax calculator 300 may compare high-sensitivity parallax images with each other, or may compare low-sensitivity parallax images with each other, so that the parallax calculator 300 can calculate a horizontal parallax or a vertical parallax. However, the center-line length between the high-sensitivity parallax images and the center-line length between the low-sensitivity parallax images may be changed, so that the parallax may not be accurately calculated.

For example, a left parallax image may be generated using the top-left low-sensitivity pixel (TL) located at the top-left side in the pixel group (PG), and a right parallax image may be generated using the top-right low-sensitivity pixel (TR) located at the top-right side in the pixel group (PG). Here, the center-line length between the center of the low-sensitivity pixel (TL) and the center of the low-sensitivity pixel (TR) may be defined as “CPL1”.

In addition, at least three high-sensitivity pixels (HP1) arranged in a “└”-shape may be binned to generate a left parallax image, and at least three high-sensitivity pixels (HP2) arranged in a “┘”-shape may be binned to generate a right parallax image. Here, the center-line length between the center of the high-sensitivity pixels (HP1) and the center of the high-sensitivity pixels (HP2) may be defined as “CPL2”.

However, the center-line length (CPL2) between the high-sensitivity pixels (HP1, HP2) and the center-line length (CPL1) between the low-sensitivity pixels (TL, TR) may be different from each other. That is, the center-line length (CPL2) between the high-sensitivity pixels (HP1, HP2) may be shorter than the center-line length (CPL1) between the low-sensitivity pixels (TL, TR). Accordingly, the parallax may be reduced in the high-sensitivity parallax image, so that autofocus may not be performed properly.

Therefore, the embodiments of the present disclosure can improve the autofocus accuracy by reducing the parallax between the high-sensitivity parallax image and the low-sensitivity parallax image. A detailed operation of the image sensing device according to the present disclosure will be described in more detail with reference to FIGS. 6A to 15B to be described below.

FIGS. 6A to 6D are diagrams illustrating a first embodiment of generating horizontal parallax images and calculating a horizontal parallax in the pixel array structure of FIG. 4 based on some embodiments of the present disclosure.

In the embodiment of FIG. 6A, a case of binning pixel signals of the pixel group (PG) including four green-color (G) pixels arranged in a (2 × 2) matrix structure will be described.

To expand the dynamic range of the image sensing device 100, the pixel group (PG) may include many more high-sensitivity pixels than the number of low-sensitivity pixels. For example, the pixel group (PG) may include four pixels (TL, TR, BL, BR) arranged in a (2 × 2) matrix structure. In the pixel group (PG), three pixels (TL, TR, BL) may be high-sensitivity pixels, and one pixel (BR) may be a low-sensitivity pixel. The four pixels (TL, TR, BL, BR) included in one pixel group (PG) may share one microlens. In the pixel group (PG), a first vertical direction will hereinafter be defined as a first column line (CL1), and a second vertical direction will hereinafter be defined as a second column line (CL2).

The binning circuit 120 may generate binning images by binning pixel signals received from the pixel array 110. The binning circuit 120 according to the present disclosure may generate a first binning image by binning pixel signals of two high-sensitivity pixels (TL, BL) arranged in the first column line (CL1) among three high-sensitivity pixels (TL, TR, BL). That is, the binning circuit 120 may generate a first binning image for adjusting the center-line length by binning pixel signals of two high-sensitivity pixels (TL, BL) disposed in the first column line (CL1) different from the second column line (CL2) where the low-sensitivity pixel (BR) is located.

According to another embodiment, the binning circuit 120 may read a pixel signal of one high-sensitivity pixel (BL) disposed in the first column line (CL1) among the three high-sensitivity pixels (TL, TR, BL), and may generate a first binning image. The binning circuit 120 may read a pixel signal of one high-sensitivity pixel (BL) disposed in the first column line (CL1) different from the second column line (CL2) where the low-sensitivity pixel (BR) is located, and may generate the first binning image for adjusting the center-line length.

In addition, the binning circuit 120 may generate a second binning image for generating the HDR image by binning the pixel signals of the three high-sensitivity pixels (TL, TR, BL). In addition, the binning circuit 120 may read a pixel signal of one low-sensitivity pixel (BR) to generate a third binning image for adjusting the center-line length. That is, the binning circuit 120 may generate a third binning image using one low-sensitivity pixel (BR) among the pixels (TR, BR) disposed in the second column line (CL2).

A process for controlling the binning circuit 120 to perform binning of pixel signals using the pixel array 110 illustrated in FIG. 4 will be described in more detail with reference to FIGS. 6B and 6C. In the embodiment of FIGS. 6B and 6C, a case in which pixel signals of the pixel blocks (PXB1, PXB2) that are adjacent to each other in the first direction and have a symmetrical structure will be described.

Referring to FIGS. 6B and 6C, the binning circuit 120 may read pixel signals of the pixel groups (PG1, PG6). For example, the binning circuit 120 may read pixel signals of high-sensitivity pixels (H1_1, H1_3) arranged in the first column line (CL1) of the pixel group (PG1), may read pixel signals of high-sensitivity pixels (H3_16, H3_18) arranged in the first column line (CL1) of the pixel group (PG6), and may generate a left high-sensitivity binning signal (LHPS). The binning circuit 120 may read a pixel signal of a low-sensitivity pixel (L1_1) arranged in the second column line (CL2) of the pixel group (PG1), may read a pixel signal of a low-sensitivity pixel (L3_6) arranged in the second column line (CL2) of the pixel group (PG6), and may generate a right low-sensitivity binning signal (RLPS).

In addition, the binning circuit 120 may read pixel signals of the pixel groups (PG3, PG8). The binning circuit 120 may read pixel signals of high-sensitivity pixels (H2_8, H2_9) arranged in the second column line (CL2) of the pixel group (PG3), may read pixel signals of high-sensitivity pixels (H4_23, H4_24) arranged in the second column line (CL2) of the pixel group (PG8), and may generate a right high-sensitivity binning signal (RHPS). The binning circuit 120 may read a pixel signal of a low-sensitivity pixel (L2_3) arranged in the first column line (CL1) of the pixel group (PG3), may read a pixel signal of a low-sensitivity pixel (L4_8) arranged in the first column line (CL1) of the pixel group (PG8), and may generate a left low-sensitivity binning signal (LLPS). A left high-sensitivity binning signal (LHPS), a right low-sensitivity binning signal (RLPS), a right high-sensitivity binning signal (RHPS), and a left low-sensitivity binning signal (LLPS) may be included in the above-described binning images (BIMG).

It can be understood that the pixel signals of the high-sensitivity pixels and the pixel signals of the low-sensitivity pixels are read in the same manner in the remaining pixel groups other than the pixel groups (PG1, PG3, PG6, PG8) of the pixel blocks (PXB1, PXB2).

Further, a process of generating parallax images by aligning phases of the binning images by the parallax image generator 130 will be described in more detail with reference to FIG. 6D. The parallax image generator 130 may generate the left parallax image and the right parallax image using pixels that have the same photosensitivity and are located symmetrically in the pixel blocks adjacent to each other in the first direction.

Referring to FIG. 6D, the parallax image generator 130 may generate a left high-sensitivity parallax image using the left high-sensitivity binning signal (LHPS) received from the high-sensitivity pixels (H1_1, H1_3, H3_16, H3_18) of the pixel groups (PG1, PG6). For example, the parallax image generator 130 may generate a left high-sensitivity parallax image using a value obtained by summing pixel signals of high-sensitivity pixels (H1_1, H1_3) of the pixel group (PG1) and another value obtained by summing pixel signals of high-sensitivity pixels (H3_16, H3_18) of the pixel group (PG6). Although the present embodiment has disclosed that the left high-sensitivity parallax image is generated by using pixel signals of two pixel groups (PG1, PG6) of the pixel block (PXB1) for convenience of description, other embodiments are also possible, and the left high-sensitivity parallax image may be generated by further using other pixel blocks in which high-sensitivity pixels have a “┌”-shaped arrangement pattern.

The parallax image generator 130 may generate a right high-sensitivity parallax image using the right high-sensitivity binning signal (RHPS) received from the high-sensitivity pixels (H2_8, H2_9, H4_23, H4_24) of the pixel groups (PG3, PG8). For example, the parallax image generator 130 may generate a right high-sensitivity parallax image using a value obtained by summing pixel signals of high-sensitivity pixels (H2_8, H2_9) of the pixel group (PG3) and another value obtained by summing pixel signals of high-sensitivity pixels (H4_23, H4_24) of the pixel group (PG8). Although the present embodiment has disclosed that the right high-sensitivity parallax image is generated by using pixel signals of two pixel groups (PG3, PG8) of the pixel block (PXB2) for convenience of description, other embodiments are also possible, and the right high-sensitivity parallax image may be generated by further using other pixel blocks in which high-sensitivity pixels have a “┐”-shaped arrangement pattern.

The parallax image generator 130 may generate a right low-sensitivity parallax image using the right low-sensitivity binning signal (RLPS) received from the low-sensitivity pixels (L1_1, L3_6) of the pixel groups (PG1, PG6). For example, the parallax image generator 130 may generate a right low-sensitivity parallax image using a value obtained by summing a pixel signal of a low-sensitivity pixel (L1_1) of the pixel group (PG1) and another value obtained by summing a pixel signal of a low-sensitivity pixel (L3_6) of the pixel group (PG6). Although the present embodiment has disclosed that the right low-sensitivity parallax image is generated by using two pixel signals for convenience of description, other embodiments are also possible, and the right low-sensitivity parallax image may be generated by further using other pixel blocks in which low-sensitivity pixels are formed on the right side of the pixel group.

The parallax image generator 130 may generate a left low-sensitivity parallax image by using the left low-sensitivity binning signal (LLPS) received from the low-sensitivity pixels (L2_3, L4_8) of the pixel groups (PG3, PG8). For example, the parallax image generator 130 may generate a left low-sensitivity parallax image using a pixel signal of the low-sensitivity pixel (L2_3) of the pixel group (PG3) and another pixel signal of the low-sensitivity pixel (L4_8) of the pixel group (PG8). Although the present embodiment has disclosed that the left low-sensitivity parallax image is generated by using two pixel signals for convenience of description, other embodiments are also possible, and the left low-sensitivity parallax image may be generated by further using other pixel blocks in which low-sensitivity pixels are formed on the left side of the pixel group.

The parallax calculator 300 may compare the left high-sensitivity parallax image generated by the parallax image generator 130 with the right high-sensitivity parallax image generated by the parallax image generator 130, and may calculate a first-directional parallax (i.e., a horizontal-directional parallax). In addition, the parallax calculator 300 may calculate a first-directional parallax (i.e., a horizontal-directional parallax) by comparing the left low-sensitivity parallax image generated by the parallax image generator 130 with the right low-sensitivity parallax image generated by the parallax image generator 130.

As described above, the image sensing device according to the present disclosure may generate a left parallax image using pixel signals of at least two pixels arranged in the first column line (CL1) located at the left side among high-sensitivity pixels included in one pixel group, and may generate a right parallax image using pixel signals of at least two pixels arranged in the second column line (CL2) located at the right side among high-sensitivity pixels included in another pixel group. In the present disclosure, the center-line length between the left high-sensitivity parallax image and the right high-sensitivity parallax image may be equal to the center-line length between the right low-sensitivity parallax image and the left low-sensitivity parallax image. Therefore, according to the present disclosure, a horizontal parallax amount (B) in the high-sensitivity image may be equal to a horizontal parallax amount (B) in the low-sensitivity image.

FIGS. 7A to 7D are diagrams illustrating a second embodiment of generating vertical parallax images and calculating a vertical parallax in the pixel array structure of FIG. 4 based on some embodiments of the present disclosure. In the embodiment of FIGS. 7A to 7D, descriptions overlapping with those of FIGS. 6A to 6D will herein be omitted, and as such, redundant descriptions thereof will herein be omitted for brevity.

Referring to FIG. 7A, a first horizontal (left-right) direction in the pixel group (PG) will hereinafter be defined as a first row line (RL1) and a second horizontal (left-right) direction in the pixel group (PG) will hereinafter be defined as a second row line (RL2).

The binning circuit 120 according to the present disclosure may generate a first binning image by binning pixel signals of two high-sensitivity pixels (TL, TR) disposed in the first row line (RL1) among three high-sensitivity pixels (TL, TR, BL). That is, the binning circuit 120 may perform binning of pixel signals of two high-sensitivity pixels (TL, TR) disposed in the first row line (RL1) different from the second row line (RL2) where the low-sensitivity pixel (BR) is located, and may generate a first binning image for adjusting the center-line length.

According to another embodiment, the binning circuit 120 may read a pixel signal of one high-sensitivity pixel (TR) disposed in the first row line (RL1) among three high-sensitivity pixels (TL, TR, BL), and may generate a first binning image. The binning circuit 120 may read a pixel signal of one high-sensitivity pixel (TR) disposed in a first row line (RL1) different from a second row line (RL2) where the low-sensitivity pixel (BR) is located, and may generate a first binning image for adjusting the center-line length.

The binning circuit 120 may generate a second binning image for generating an HDR image by binning the pixel signals of three high-sensitivity pixels (TL, TR, BL). In addition, the binning circuit 120 may read the pixel signal of one low-sensitivity pixel (BR), and may generate a third binning image for adjusting the center-line length. That is, the binning circuit 120 may generate a third binning image by using one low-sensitivity pixel (BR) among the pixels (BL, BR) disposed in the second row line (RL2).

A process for controlling the binning circuit 120 to perform binning of the pixel signal using the pixel array 110 of FIG. 3 will be described in more detail with reference to FIGS. 7B and 7C. In the embodiment of FIGS. 7B and 7C, a case in which the pixel signals of the pixel blocks (PXB1, PXB3) that are adjacent to each other in the second direction and have a symmetrical structure will be described for convenience of description.

Referring to FIGS. 7B and 7C, the binning circuit 120 may read pixel signals of the pixel groups (PG1, PG6). For example, the binning circuit 120 may read pixel signals of high-sensitivity pixels (H1_1, H1_2) arranged in the first row line (RL1) of the pixel group (PG1), may read pixel signals of high-sensitivity pixels (H3_16, H3_17) arranged in the first row line (RL1) of the pixel group (PG6), and may generate a top high-sensitivity binning signal (THPS). The binning circuit 120 may read a pixel signal of the low-sensitivity pixel (L1_1) arranged in the second row line (RL2) of the pixel group (PG1), may read a pixel signal of the low-sensitivity pixel (L3_6) arranged in the second row line (RL2) of the pixel group (PG6), and may generate a bottom low-sensitivity binning signal (BLPS).

The binning circuit 120 may read pixel signals of the pixel groups (PG9, PG14). The binning circuit 120 may read pixel signals of the high-sensitivity pixels (H5_26, H5_27) arranged in the second row line (RL2) of the pixel group (PG9), may read pixel signals of the high-sensitivity pixels (H7_41, H7_42) arranged in the second row line (RL2) of the pixel group (PG14), and may generate a bottom high-sensitivity binning signal (BHPS). The binning circuit 120 may read a pixel signal of the low-sensitivity pixel (L5_9) arranged in the first row line (RL1) of the pixel group (PG9), may read a pixel signal of the low-sensitivity pixel (L7_14) arranged in the first row line (RL1) of the pixel group (PG14), and may generate a top low-sensitivity binning signal (TLPS).

It can be understood that the pixel signals of the high-sensitivity pixels and the pixel signals of the low-sensitivity pixels are read in the same manner in the remaining pixel groups other than the pixel groups (PG1, PG6, PG9, PG14) of the pixel blocks (PXB1, PXB3).

A process of generating parallax images by aligning phases of the binning images by the parallax image generator 130 will be described in more detail with reference to FIG. 7D. The parallax image generator 130 may generate the top parallax image and the bottom parallax image by using pixels that have the same photosensitivity and are located symmetrically in the pixel blocks adjacent to each other in the second direction.

Referring to FIG. 7D, the parallax image generator 130 may generate a top high-sensitivity parallax image by using the top high-sensitivity binning signal (THPS) received from the high-sensitivity pixels (H1_1, H1_2, H3_16, H3_17) of the pixel groups (PG1, PG6). For example, the parallax image generator 130 may generate a top high-sensitivity parallax image using a value obtained by summing pixel signals of high-sensitivity pixels (H1_1, H1_2) of the pixel group (PG1) and another value obtained by summing pixel signals of high-sensitivity pixels (H3_16, H3_17) of the pixel group (PG6). Although the present embodiment has disclosed that the top high-sensitivity parallax image is generated by using pixel signals of two pixel groups (PG1, PG6) of the pixel block (PXB1) for convenience of description, other embodiments are also possible, and the top high-sensitivity parallax image may be generated by further using other pixel blocks in which high-sensitivity pixels have a “┌”-shaped arrangement pattern.

The parallax image generator 130 may generate a bottom high-sensitivity parallax image by using the bottom high-sensitivity binning signal (BHPS) received from the high-sensitivity pixels (H5_26, H5_27, H7_41, H7_42) of the pixel groups (PG9, PG14). For example, the parallax image generator 130 may generate a bottom high-sensitivity parallax image using a value obtained by summing pixel signals of high-sensitivity pixels (H5_26, H5_27) of the pixel group (PG9) and another value obtained by summing pixel signals of high-sensitivity pixels (H7_41, H7_42) of the pixel group (PG14). Although the present embodiment has disclosed that the bottom high-sensitivity parallax image is generated by using pixel signals of two pixel groups (PG9, PG14) of the pixel block (PXB2) for convenience of description, other embodiments are also possible, and the bottom high-sensitivity parallax image may be generated by further using other pixel blocks in which high-sensitivity pixels have a “└”-shaped arrangement pattern.

The parallax image generator 130 may generate a bottom low-sensitivity parallax image by using the bottom low-sensitivity binning signal (BLPS) received from the low-sensitivity pixels (L1_1, L3_6) of the pixel groups (PG1, PG6). For example, the parallax image generator 130 may generate a bottom low-sensitivity parallax image by using a pixel signal of the low-sensitivity pixel (L1_1) of the pixel group (PG1) and another pixel signal of the low-sensitivity pixel (L3_6) of the pixel group (PG6). Although the present embodiment has disclosed that the bottom low-sensitivity parallax image is generated by using two pixel signals for convenience of description, other embodiments are also possible, and the bottom low-sensitivity parallax image may be generated by further using other pixel blocks in which low-sensitivity pixels are formed below the pixel group.

The parallax image generator 130 may generate a top low-sensitivity parallax image by using the top low-sensitivity binning signal (TLPS) received from the low-sensitivity pixels (L5_9, L7_14) of the pixel groups (PG9, PG14). For example, the parallax image generator 130 may generate a top low-sensitivity parallax image by using a pixel signal of the low-sensitivity pixel (L5_9) of the pixel group (PG9) and another pixel signal of the low-sensitivity pixel (L7_14) of the pixel group (PG14). Although the present embodiment has disclosed that the top low-sensitivity parallax image is generated by using two pixel signals for convenience of description, other embodiments are also possible, and the top low-sensitivity parallax image may be generated by further using other pixel blocks in which low-sensitivity pixels are formed above the pixel group.

The parallax calculator 300 may compare the top high-sensitivity parallax image and the bottom high-sensitivity parallax image generated by the parallax image generator 130 with each other, and may calculate a second-directional parallax (i.e., a vertical-directional parallax). In addition, the parallax calculator 300 may calculate a second-directional parallax (i.e., a vertical-directional parallax) by comparing the top low-sensitivity parallax image and the bottom low-sensitivity parallax image generated by the parallax image generator 130 with each other.

As described above, the image sensing device according to the present disclosure may generate a top parallax image by using pixel signals of at least two pixels arranged in the first row line (RL1) located at the upper side among high-sensitivity pixels included in one pixel group, and may generate a bottom parallax image by using pixel signals of at least two pixels arranged in the second row line (RL2) located at the lower side among high-sensitivity pixels included in another pixel group. In the present disclosure, the center-line length between the top high-sensitivity parallax image and the bottom high-sensitivity parallax image may be equal to the center-line length between the top low-sensitivity parallax image and the bottom low-sensitivity parallax image. Therefore, according to the present disclosure, a vertical parallax amount (B) in the high-sensitivity image may be equal to a vertical parallax amount (B) in the low-sensitivity image.

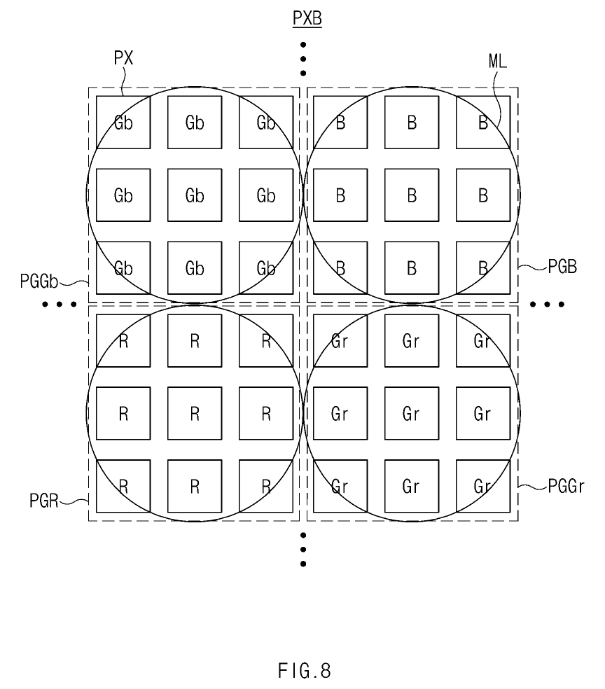

FIG. 8 is a diagram illustrating another embodiment of a structure of a pixel block in the pixel array of FIG. 2 based on some embodiments of the present disclosure. In the embodiment of FIG. 8, descriptions overlapping with those of FIG. 3 will herein be omitted, and as such, redundant descriptions thereof will herein be omitted for brevity.

Referring to FIG. 8, each pixel block (PXB) included in the pixel array 110 may include a plurality of pixel groups (PGR, PGGr, PGGb, PGB) arranged adjacent to each other. Each pixel group (PGR, PGGb, PGGr, PGB) may include the plurality of pixels (PXs) that share one microlens (ML) and have a color filter of the same color.

The pixels (PX) of each pixel group (PGR, PGGb, PGGr, PGB) may be arranged adjacent to each other in an (M × N) matrix structure, where “M” and “N” are integers greater than or equal to 3 and may be the same or different from each other. For example, the pixel group (PGR) may include nine red-color (R) pixels (PXs) arranged in a (3 × 3) matrix structure while sharing one microlens (ML). Each of the pixel groups (PGGr, PGGb) may include nine green-color (Gr, Gb) pixels (PXs) arranged in a (3 × 3) matrix structure while sharing one microlens (ML). The pixel group (PGB) may include nine blue-color (B) pixels (PXs) arranged in a (3 × 3) matrix structure while sharing one microlens (ML). The pixel groups (PGR, PGGr, PGGb, PGB) may be arranged in a Bayer pattern.

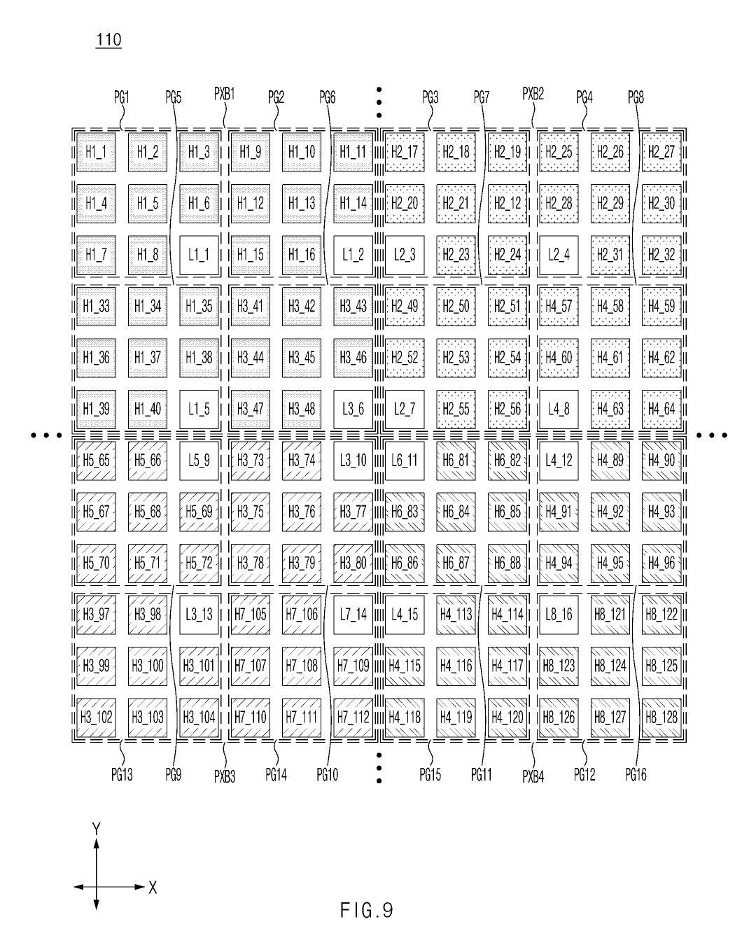

FIG. 9 is a diagram illustrating another embodiment of a structure in which pixel blocks are consecutively arranged in the pixel array of FIG. 2 based on some embodiments of the present disclosure. In the embodiment of FIG. 9, descriptions overlapping with those of FIG. 4 will herein be omitted, and as such, redundant descriptions thereof will herein be omitted for brevity.

Referring to FIG. 9, each pixel block (PXB1~PXB4) may include a plurality of pixel groups (PG1~PG16) arranged adjacent to each other. The plurality of pixel groups (PG1~PG16) may include high-sensitivity pixels (H1_1~H8_128) and low-sensitivity pixels (L1_1~L8_16) for generating an HDR image.

In the present embodiment, each pixel group (PG) of the pixel blocks (PXB1~PXB4) may include eight high-sensitivity pixels and one low-sensitivity pixel. The arrangement patterns of the high-sensitivity pixels and the low-sensitivity pixels between the pixel blocks (PXB1~PXB4) adjacent to each other in the first direction may be symmetrical to each other in the first direction. The arrangement patterns of the high-sensitivity pixels and the low-sensitivity pixels between the pixel blocks (PXB1~PXB4) adjacent to each other in the second direction may be symmetrical to each other in the second direction.

For example, high-sensitivity pixels (H1_1~H1_8, H1_9~H1_16, H1_33~H1_40, H3_41~H3_48) in the pixel groups (PG1, PG2, PG5, PG6) of the pixel block (PXB1) may have an arrangement pattern formed in the shape of “┌”. High-sensitivity pixels (H2_17~H2_24, H2_25~H2_32, H2_49~H2_56, H4_57~H4_64) in the pixel groups (PG3, PG4, PG7, PG8) of the pixel block (PXB2) adjacent to the pixel block (PXB1) in the first direction may have an arrangement pattern formed in the shape of “┐”.

High-sensitivity pixels (H5_65~H5_72, H3_73~H3_80, H3_97~H3_104, H7_105~H7_112) in the pixel groups (PG9, PG10, PG13, PG14) of the pixel block (PXB3) adjacent to the pixel block (PXB1) in the second direction may have an arrangement pattern formed in the shape of “└”. High-sensitivity pixels (H6_81~H6_88, H4_89~H4_96, H4_113~H4_120, H8_121~H8_128) in the pixel groups (PG11, PG12, PG15, PG16) of the pixel block (PXB4) adjacent to toe pixel block (PXB3) in the first direction may have an arrangement pattern formed in the shape of “┘”.

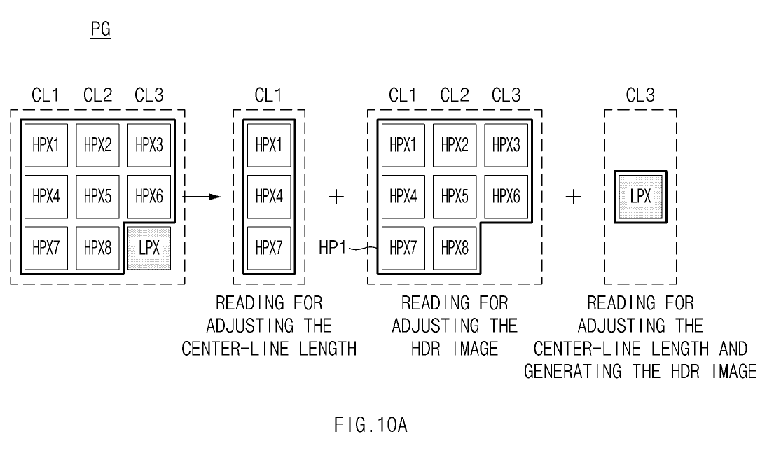

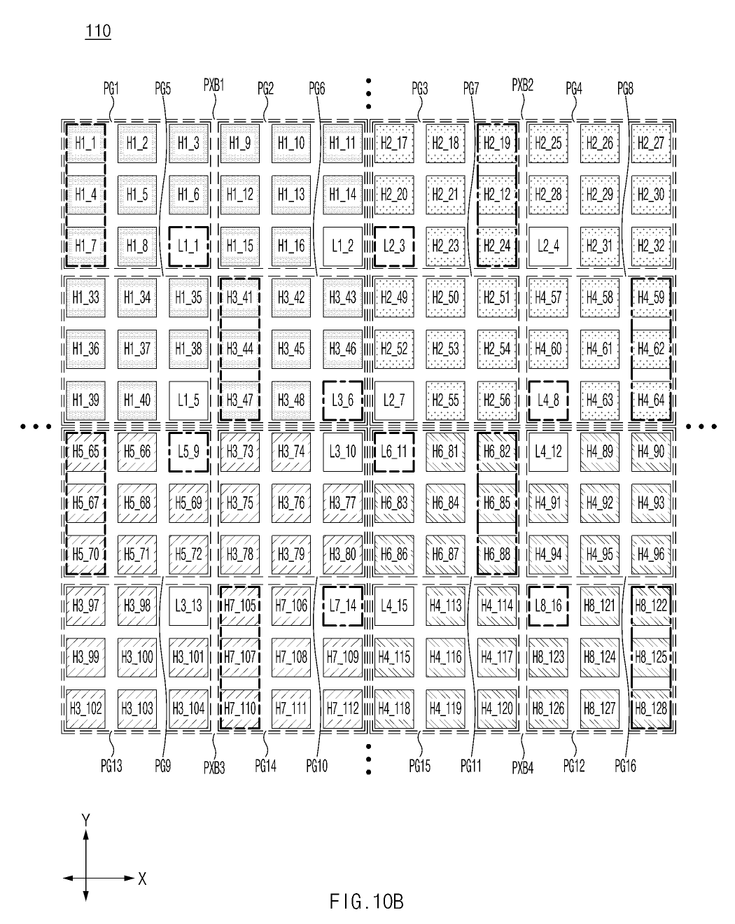

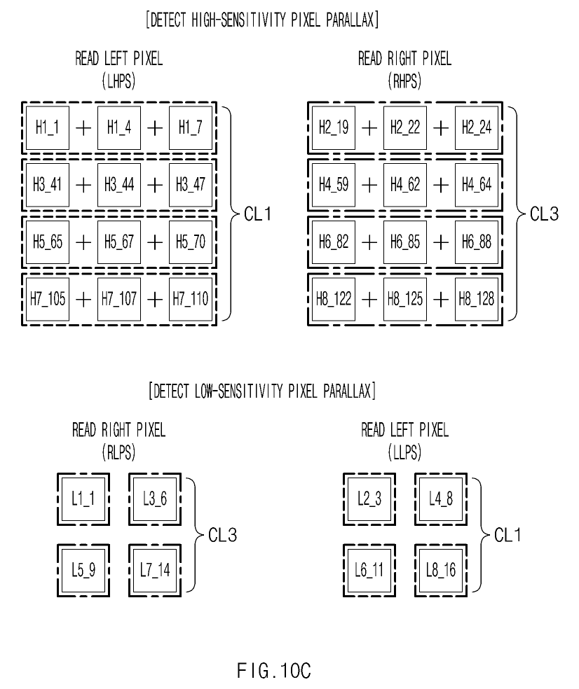

FIGS. 10A to 10C are diagrams illustrating a third embodiment of generating horizontal parallax images and calculating horizontal parallax in the pixel array structure of FIG. 9 based on some embodiments of the present disclosure. In the embodiment of FIGS. 10A to 10C, descriptions overlapping with those of FIGS. 6A to 6D will herein be omitted, and as such redundant descriptions thereof will herein be omitted for brevity.

In the embodiment of FIG. 10A, a case of binning pixel signals of the pixel group (PG) including nine green-color (G) pixels (PXs) arranged in a (3 × 3) matrix structure will be described.

For example, in the pixel group (PG), eight pixels (HPX1~HPX8) may be high-sensitivity pixels, and one pixel (LPX) may be a low-sensitivity pixel. Nine pixels (HPX1~HPX8, LPX) included in one pixel group (PG) may share one microlens. In the pixel group (PG), a first vertical (up-down) direction will hereinafter be defined as a first column line (CL1), a second vertical direction will hereinafter be defined as a second column line (CL2), and a third vertical direction will hereinafter be defined as a third column line (CL3).

The binning circuit 120 according to the present disclosure may generate a first binning image by binning pixel signals of three high-sensitivity pixels (HPX1, HPX4, HPX7) arranged in the first column line (CL1) among the eight high-sensitivity pixels (HPX1~HPX8). That is, the binning circuit 120 may generate a first binning image for adjusting the center-line length by binning pixel signals of three high-sensitivity pixels (HPX1, HPX4, HPX7) arranged in the first column line (CL1) different from the third column line (CL3) where the low-sensitivity pixel (LPX) is located. In addition, the binning circuit 120 may generate a second binning image for generating an HDR image by binning pixel signals of eight pixels (HPX1~ HPX8). In addition, the binning circuit 120 may generate a third binning image for adjusting the center-line length by reading a pixel signal of one low-sensitivity pixel (LPX) arranged in the third column line (CL3). That is, the binning circuit 120 may generate the third binning image by using one low-sensitivity pixel (LPX) among the pixels (HPX3, HPX6, LPX) arranged in the third column line (CL3).

A process for controlling the binning circuit 120 to perform binning of one or more pixel signals using the pixel array 110 illustrated in FIG. 9 will be described in more detail with reference to FIGS. 10B and 10C.

Referring to FIGS. 10B and 10C, the binning circuit 120 may read pixel signals of pixel groups (PG1, PG3, PG6, PG8, PG9, PG11, PG14, PG16).

For example, the binning circuit 120 may read pixel signals of high-sensitivity pixels (H1_1, H1_4, H1_7) arranged in the first column line (CL1) of the pixel group (PG1). The binning circuit 120 may read pixel signals of high-sensitivity pixels (H3_41, H3_44, H3_47) arranged in the first column line (CL1) of the pixel group (PG6). In this way, the binning circuit 120 may generate a left high-sensitivity binning signal (LHPS).

The binning circuit 120 may read pixel signals of high-sensitivity pixels (H2_19, H2_22, H2_24) arranged in the third column line (CL3) of the pixel group (PG3). The binning circuit 120 may read pixel signals of high-sensitivity pixels (H4_59, H4_62, H4_64) arranged in the third column line (CL3) of the pixel group (PG8). In this way, the binning circuit 120 may generate a right high-sensitivity binning signal (RHPS).

The binning circuit 120 may read the pixel signal of the low-sensitivity pixel (L1_1) arranged in the third column line (CL3) of the pixel group (PG1). The binning circuit 120 may read the pixel signal of the low-sensitivity pixel (L3_6) arranged in the third column line (CL3) of the pixel group (PG6). In this way, the binning circuit 120 may generate the right low-sensitivity binning signal (RLPS).

The binning circuit 120 may read the pixel signal of the low-sensitivity pixel (L2_3) arranged in the first column line (CL1) of the pixel group (PG3). The binning circuit 120 may read the pixel signal of the low-sensitivity pixel (L4_8) arranged in the first column line (CL1) of the pixel group (PG8). In this way, the binning circuit 120 may generate the left low-sensitivity binning signal (LLPS).

It can be understood that the pixel signals of the high-sensitivity pixels and the pixel signals of the low-sensitivity pixels are read in the same manner in the remaining pixel groups (PG9, PG11, PG14, PG16) other than the pixel groups (PG1, PG3, PG6, PG8) of the pixel blocks (PXB1, PXB2).

The parallax image generator 130 may generate a left high-sensitivity parallax image by using a left high-sensitivity binning signal (LHPS) received from high-sensitivity pixels (H1_1, H1_4, H1_7, H3_41, H3_44, H3_47, H5_65, H5_67, H5_70, H7_105, H7_107, H7_110) of the pixel groups (PG1, PG6, PG9, PG14). For example, the parallax image generator 130 may generate a left high-sensitivity parallax image by using a first value obtained by summing pixel signals of high-sensitivity pixels (H1_1, H1_4, H1_7) of the pixel group (PG1), a second value obtained by summing pixel signals of high-sensitivity pixels (H3_41, H3_44, H3_47) of the pixel group (PG6), a third value obtained by summing pixel signals of high-sensitivity pixels (H5_65, H5_67, H5_70) of the pixel group (PG9), and a fourth value obtained by summing pixel signals of high-sensitivity pixels (H7_105, H7_107, H7_110) of the pixel group (PG14).

As described above, the image sensing device according to the present embodiment may generate a left high-sensitivity parallax image by using pixel signals of high-sensitivity pixels arranged in the first column line (CL1) in the four pixel groups (PG1, PG6, PG9, PG14) each having a “┌”-shaped arrangement pattern.

The parallax image generator 130 may generate a right high-sensitivity parallax image by using the right high-sensitivity binning signal (RHPS) received from high-sensitivity pixels (H2_19, H2_22, H2_24, H4_59, H4_62, H4_64, H6_82, H6_85, H6_88, H8_122, H8_125, H8_128) of the pixel groups (PG3, PG8, PG11, PG16). For example, the parallax image generator 130 may generate a right high-sensitivity parallax image by using a first value obtained by summing pixel signals of high-sensitivity pixels (H2_19, H2_22, H2_24) of the pixel group (PG3), a second value obtained by summing pixel signals of high-sensitivity pixels (H4_59, H4_62, H4_64) of the pixel group (PG8), a third value obtained by summing pixel signals of high-sensitivity pixels (H6_82, H6_85, H6_88) of the pixel group (PG11), and a fourth value obtained by summing pixel signals of high-sensitivity pixels (H8_122, H8_125, H8_128) of the pixel group (PG16).

As described above, the image sensing device according to the present embodiment may generate a right high-sensitivity parallax image by using pixel signals of high-sensitivity pixels arranged in the third column line (CL3) in the four pixel groups (PG3, PG8, PG11, PG16) each having a “┐”-shaped arrangement pattern.

The parallax image generator 130 may generate a right low-sensitivity parallax image by using the right low-sensitivity binning signal (RLPS) received from low-sensitivity pixels (L1_1, L3_6, L5_9, L7_14) of the pixel groups (PG1, PG6, PG9, PG14). The parallax image generator 130 may generate a left low-sensitivity parallax image by using the left low-sensitivity binning signal (LLPS) received from low-sensitivity pixels (L2_3, L4_8, L6_11, L8_16) of the pixel groups (PG3, PG8, PG11, PG16).

As described above, the image sensing device according to the present disclosure may generate a left parallax image by using pixel signals of at least three pixels arranged in the first column line (CL1) located at the left side among high-sensitivity pixels included in one pixel group, and may generate a right parallax image by using pixel signals of at least three pixels arranged in the third column line (CL3) located at the right side among high-sensitivity pixels included in another pixel group.

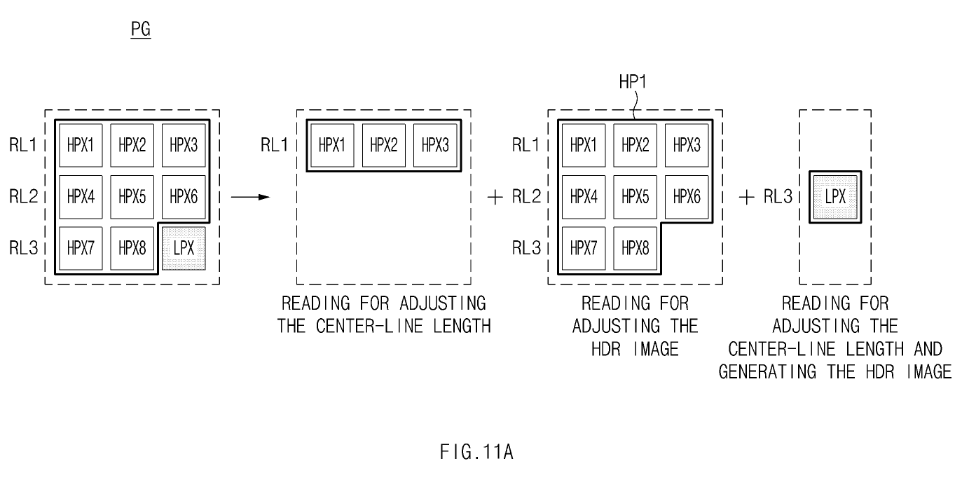

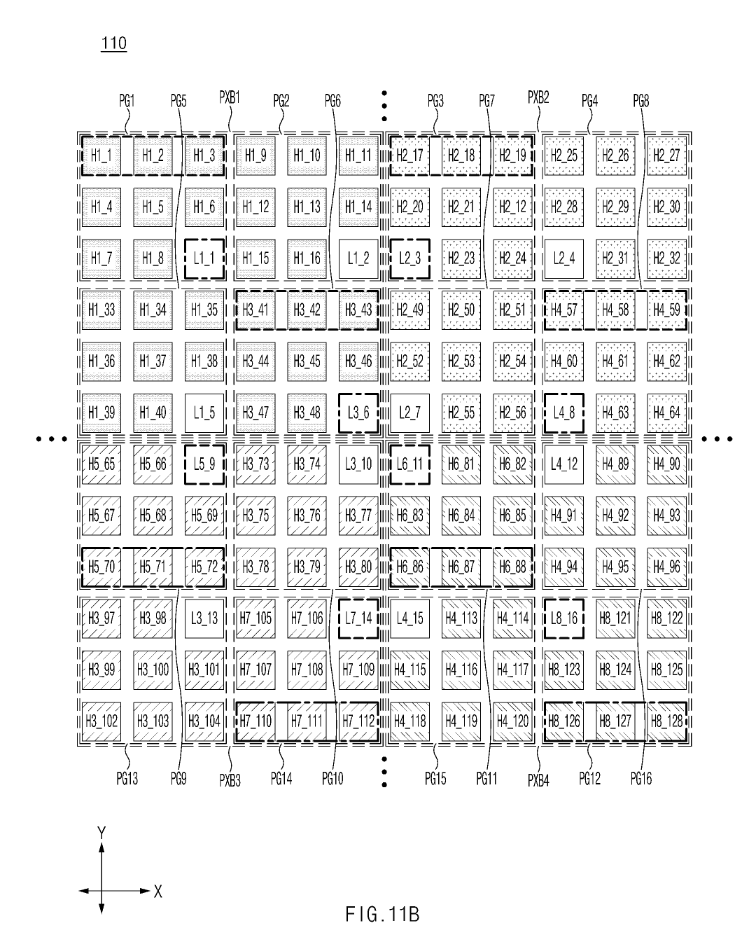

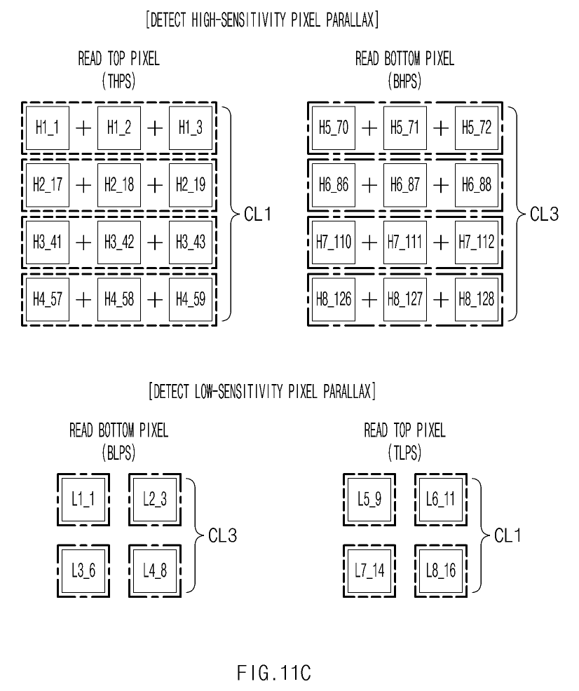

FIGS. 11A to 11C are diagrams illustrating a fourth embodiment of generating vertical parallax images and calculating a vertical parallax in the pixel array structure of FIG. 9 based on some embodiments of the present disclosure. In the embodiment of FIGS. 11A to 11C, descriptions overlapping with those of FIGS. 10A to 10C will herein be omitted, and as such, redundant descriptions thereof will herein be omitted for brevity.

Referring to FIG. 11A, in the pixel group (PG), the first horizontal (left-right) direction will hereinafter be defined as the first row line (RL1), the second horizontal direction will hereinafter be defined as the second row line (RL2), and the third horizontal direction will hereinafter be defined as the third row line (RL3).

The binning circuit 120 according to the present disclosure may generate a first binning image by binning pixel signals of three high-sensitivity pixels (HPX1, HPX2, HPX3) arranged in the first row line (RL1) among eight high-sensitivity pixels (HPX1~HPX8). That is, the binning circuit 120 may generate a first binning image for adjusting the center-line length by binning pixel signals of three high-sensitivity pixels (HPX1, HPX2, HPX3) disposed in the first row line (RL1) different from the third row line (RL3) where the low-sensitivity pixel (LPX) is located. In addition, the binning circuit 120 may generate a second binning image for generating an HDR image by binning pixel signals of eight high-sensitivity pixels (HPX1~HPX8). In addition, the binning circuit 120 may generate a third binning image for adjusting the center-line length by reading a pixel signal of one low-sensitivity pixel (LPX) disposed in the third row line (RL3). That is, the binning circuit 120 may generate a third binning image by using one low-sensitivity pixel (LPX) among the pixels (HPX7, HPX8, LPX) disposed in the third row line (RL3).

A process for controlling the binning circuit 120 to perform binning of the pixel signal using the pixel array 110 illustrated in FIG. 9 will be described in more detail with reference to FIGS. 11B and 11C.

Referring to FIGS. 11B and 11C, the binning circuit 120 may read pixel signals of the pixel groups (PG1, PG3, PG6, PG8, PG9, PG11, PG14, PG16).

For example, the binning circuit 120 may read pixel signals of high-sensitivity pixels (H1_1, H1_2, H1_3) arranged in the first row line (RL1) of the pixel group (PG1). The binning circuit 120 may read pixel signals of high-sensitivity pixels (H2_17, H2_18, H2_19) arranged in the first row line (RL1) of the pixel group (PG3). In this way, the binning circuit 120 may generate a top high-sensitivity binning signal (THPS).

The binning circuit 120 may read pixel signals of high-sensitivity pixels (H5_70, H5_71, H5_72) arranged in the third row line (RL3) of the pixel group (PG9). The binning circuit 120 may read pixel signals of high-sensitivity pixels (H6_86, H6_87, H6_88) arranged in the third row line (RL3) of the pixel group (PG11). In this way, the binning circuit 120 may generate a bottom high-sensitivity binning signal (BHPS).

The binning circuit 120 may read the pixel signal of the low-sensitivity pixel (L1_1) arranged in the third row line (RL3) of the pixel group (PG1). The binning circuit 120 may read the pixel signal of the low-sensitivity pixel (L2_3) arranged in the third row line (RL3) of the pixel group (PG3). In this way, the binning circuit 120 may generate a bottom low-sensitivity binning signal (BLPS).

The binning circuit 120 may read the pixel signal of the low-sensitivity pixel (L5_9) arranged in the first row line (RL1) of the pixel group (PG9). The binning circuit 120 may read the pixel signal of the low-sensitivity pixel (L6_11) arranged in the first row line (RL1) of the pixel group (PG11). In this way, the binning circuit 120 may generate a top low-sensitivity binning signal (TLPS).

It can be understood that the pixel signals of the high-sensitivity pixels and the pixel signals of the low-sensitivity pixels are read in the same manner in the remaining pixel groups (PG6, PG8, PG14, PG16) other than the pixel groups (PG1, PG3, PG9, PG11).

The parallax image generator 130 may generate a top high-sensitivity parallax image by using the top high-sensitivity binning signal (THPS) received from high-sensitivity pixels (H1_1, H1_2, H1_3, H2_17, H2_18, H2_19, H3_41, H3_42, H3_43, H4_57, H4_58, H4_59) of the pixel groups (PG1, PG3, PG6, PG8). For example, the parallax image generator 130 may generate a top high-sensitivity parallax image by using a first value obtained by summing pixel signals of high-sensitivity pixels (H1_1, H1_2, H1_3) of the pixel group (PG1), a second value obtained by summing pixel signals of high-sensitivity pixels (H2_17, H2_18, H2_19) of the pixel group (PG3), a third value obtained by summing pixel signals of high-sensitivity pixels (H3_41, H3_42, H3_43) of the pixel group (PG6), and a fourth value obtained by summing pixel signals of high-sensitivity pixels (H4_57, H4_58, H4_59) of the pixel group (PG8).

As described above, the image sensing device according to the present embodiment may generate a top high-sensitivity parallax image by using pixel signals of high-sensitivity pixels arranged in the first row line (RL1).

The parallax image generator 130 may generate a bottom high-sensitivity parallax image by using the bottom high-sensitivity binning signal (BHPS) received from high-sensitivity pixels (H5_70, H5_71, H5_72, H6_86, H6_87, H6_88, H7_110, H7_111, H7_112, H8_126, H8_127, H8_128) of the pixel groups (PG9, PG11, PG14, PG16). For example, the parallax image generator 130 may generate a bottom high-sensitivity parallax image by using a first value obtained by summing pixel signals of high-sensitivity pixels (H5_70, H5_71, H5_72) of the pixel group (PG9), a second value obtained by summing pixel signals of high-sensitivity pixels (H6_86, H6_87, H6_88) of the pixel group (PG11), a third value obtained by summing pixel signals of high-sensitivity pixels (H7_110, H7_111, H7_112) of the pixel group (PG14), and a fourth value obtained by summing pixel signals of high-sensitivity pixels (H8_126, H8_127, H8_128) of the pixel group (PG16).

As described above, the image sensing device according to the present embodiment may generate a bottom high-sensitivity parallax image by using the pixel signals of the high-sensitivity pixels arranged in the third row line (RL3).

The parallax image generator 130 may generate a bottom low-sensitivity parallax image by using the bottom low-sensitivity binning signal (BLPS) received from the low-sensitivity pixels (L1_1, L2_3, L3_6, L4_8) of the pixel groups (PG1, PG3, PG6, PG8). The parallax image generator 130 may generate a top low-sensitivity parallax image by using the top low-sensitivity binning signal (TLPS) received from the low-sensitivity pixels (L5_9, L6_11, L7_14, L8_16) of the pixel groups (PG9, PG11, PG14, PG16).

As described above, the image sensing device according to the present disclosure may generate a top parallax image by using pixel signals of at least three pixels arranged in the first row line (RL1) located at the upper side among high-sensitivity pixels included in one pixel group, and may generate a bottom parallax image by using pixel signals of at least three pixels arranged in the third row line (RL3) located at the lower side among high-sensitivity pixels included in another pixel group.

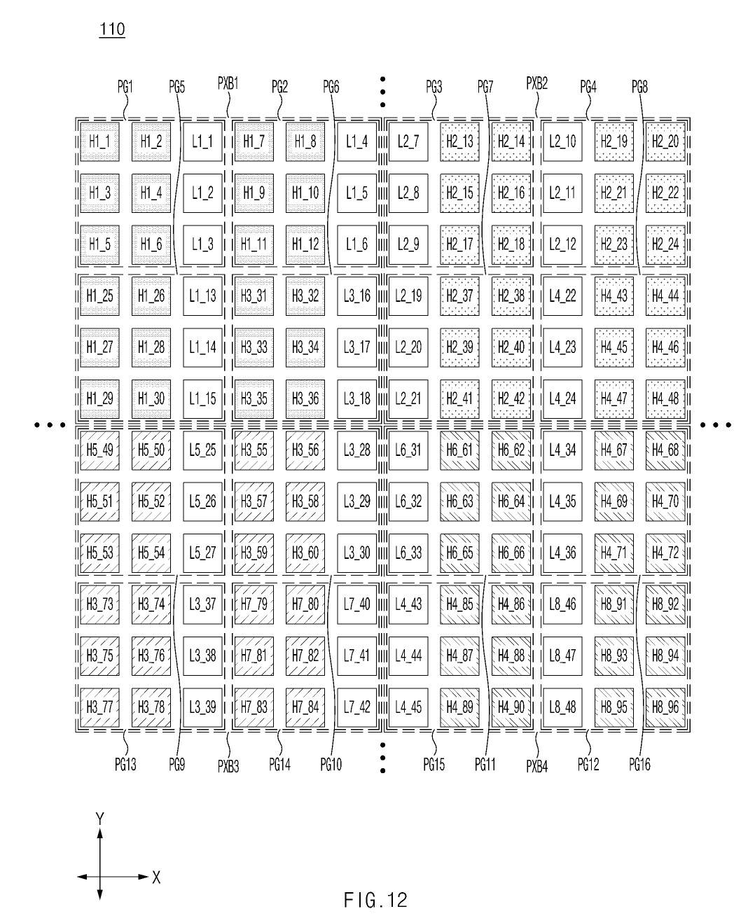

FIG. 12 is a diagram illustrating another embodiment of a structure in which pixel blocks are consecutively arranged in the pixel array of FIG. 2 based on some embodiments of the present disclosure. In the embodiment of FIG. 12, descriptions overlapping with those of FIG. 9 will herein be omitted, and as such, redundant descriptions thereof will herein be omitted for brevity.

Referring to FIG. 12, each pixel block (PXB1~PXB4) may include a plurality of pixel groups (PG1~PG16) arranged adjacent to each other. The plurality of pixel groups (PG1~PG16) may include high-sensitivity pixels (H1_1~H8_96) and low-sensitivity pixels (L1_1~L8_48) for generating an HDR image.

In the present embodiment, each pixel group (PG) of the pixel blocks (PXB1~PXB4) may include six high-sensitivity pixels and three low-sensitivity pixels. The arrangement patterns of high-sensitivity pixels and low-sensitivity pixels between pixel blocks (PXB1~PXB4) adjacent to each other in the first direction may be symmetrical to each other in the first direction, and the arrangement patterns of high-sensitivity pixels and low-sensitivity pixels between pixel blocks (PXB1~PXB4) adjacent to each other in the second direction may be symmetrical to each other in the second direction.

For example, in the two adjacent pixel blocks (PXB1, PXB2) located at the upper side among the pixel blocks (PXB1~PXB4), the high-sensitivity pixels and the low-sensitivity pixels may be located opposite to each other in the first direction.

In each pixel group (PG1, PG2, PG5, PG6) of the pixel block (PXB1), among the nine pixels arranged in a (3 × 3) matrix structure, six pixels arranged in a (2 × 3) matrix structure located at the left side may be high-sensitivity pixels (H1_1~H1_6, H1_7~H1_12, H1_25~H1_30, H3_31~H3_36), and three pixels arranged in a (1 × 3) matrix structure located at the right side may be low-sensitivity pixels (L1_1~L1_3, L1_4~L1_6, L1_13~L1_15, L3_16~L3_18).

On the other hand, in each pixel group (PG3, PGb, PG7, PG8) of the pixel block (PXB2), among the nine pixels arranged in a (3 × 3) matrix structure, six pixels arranged in a (2 × 3) matrix structure located at the right side may be high-sensitivity pixels (H2_13~H2_18, H2_19~H2_24, H2_37~H2_42, H4_43~H4_48), and three pixels arranged in a (1 × 3) matrix structure located at the left side may be low-sensitivity pixels (L2_7~L2_9, L2_10~L2_12, L2_19~L2_21, L4_22~L4_24).

In the two adjacent pixel blocks (PXB3, PXB4) located at the lower side among the pixel blocks (PXB1~PXB4), the high-sensitivity pixels and the low-sensitivity pixels may be located opposite to each other in the first direction.

In each pixel group (PG9, PG10, PG13, PG14) of the pixel block (PXB3), among the nine pixels arranged in a (3 × 3) matrix structure, six pixels arranged in a (2 × 3) matrix structure located at the left side may be high-sensitivity pixels (H5_49~H5_54, H3_55~H3_60, H3_73~H3_78, H7_79~H7_84), and three pixels arranged in a (1 × 3) matrix structure located at the right side may be low-sensitivity pixels (L5_25~L5_27, L3_28~L3_30, L3_37~L3_39, L7_40~L7_42).

On the other hand, in each pixel group (PG11, PG12, PG15, PG16) of the pixel block (PXB4), among the nine pixels arranged in a (3 × 3) matrix structure, six pixels arranged in a (2 × 3) matrix structure located at the right side may be high-sensitivity pixels (H6_61~H6_66, H4_67~H4_72, H4_85~H4_90, H8_91~H8_96), and three pixels arranged in a (1 × 3) matrix structure located at the left side may be low-sensitivity pixels (L6_31~L6_33, L4_34~L4_36, L4_43~L4_45, L8_46~L8_48).

The pixel blocks (PXB1~PXB4) arranged as in FIG. 12 may be formed in various positions within the pixel array 110. In addition, the positions of the high-sensitivity pixels and the positions of the low-sensitivity pixels may be interchanged in the arrangement structure of FIG. 12. For example, the low-sensitivity pixels may be formed at the positions of the high-sensitivity pixels shown in FIG. 12, and the high-sensitivity pixels may be formed at the positions of the low-sensitivity pixels shown in FIG. 12.

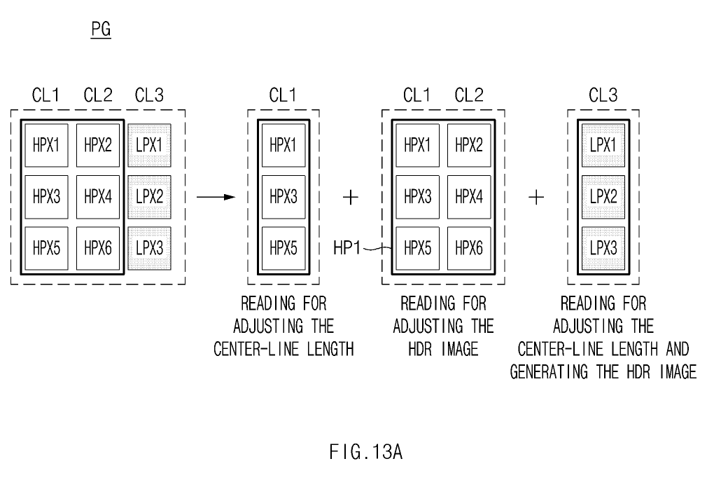

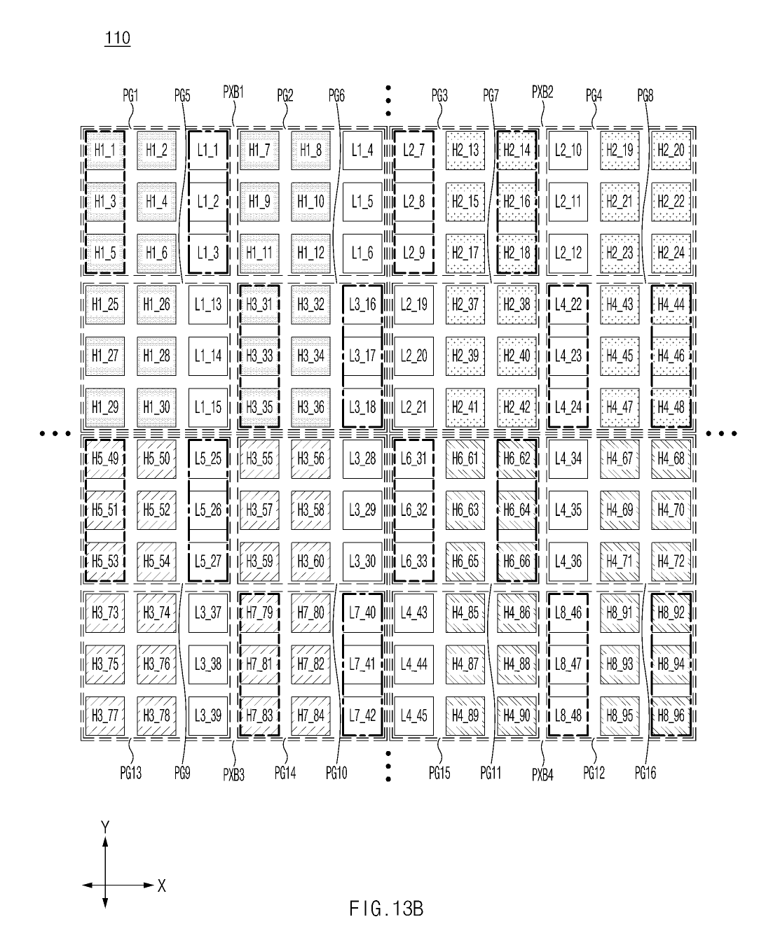

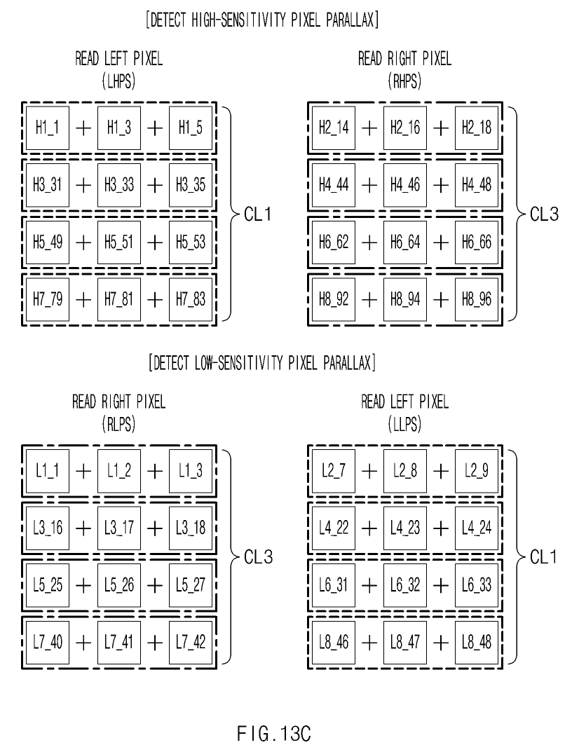

FIGS. 13A to 13C are diagrams illustrating a fifth embodiment of generating horizontal parallax images and calculating a horizontal parallax in the pixel array structure of FIG. 12 based on some embodiments of the present disclosure. In the embodiment of FIGS. 13A to 13C, descriptions overlapping with those of FIGS. 11A and 11B will herein be omitted, and as such, redundant descriptions thereof will herein be omitted for brevity.

Referring to FIG. 13A, six pixels (HPX1~HPX6) in the pixel group (PG) may be high-sensitivity pixels, and three pixels (LPX1~LPX3) in the pixel group (PG) may be low-sensitivity pixels. Nine pixels (HPX1~HPX6,LPX1~LPX3) included in one pixel group (PG) may share one microlens.

The binning circuit 120 according to the present disclosure may generate a first binning image by binning pixel signals of three high-sensitivity pixels (HPX1, HPX3, HPX5) arranged in the first column line (CL1) among six high-sensitivity pixels (HPX1~HPX6). That is, the binning circuit 120 may generate a first binning image for adjusting the center-line length by binning pixel signals of three high-sensitivity pixels (HPX1, HPX3, HPX5) arranged in the first column line (CL1) different from the third column line (CL3) where low-sensitivity pixels (LPX1~LPX3) are located. In addition, the binning circuit 120 may generate a second binning image for generating an HDR image by binning pixel signals of six high-sensitivity pixels (HPX1~HPX6). In addition, the binning circuit 120 may generate a third binning image for adjusting the center-line length by binning the pixel signals of three low-sensitivity pixels (LPX1~LPX3) arranged in the third column line (CL3).

A process for controlling the binning circuit 120 to perform binning of the pixel signal using the pixel array 110 illustrated in FIG. 12 will be described in more detail with reference to FIGS. 13B and 13C.

Referring to FIGS. 13B and 13C, the binning circuit 120 may read the pixel signals of the pixel groups (PG1, PG3, PG6, PG8, PG9, PG11, PG14, PG16).

For example, the binning circuit 120 may read pixel signals of high-sensitivity pixels (H1_1, H1_3, H1_5) arranged in the first column line (CL1) of the pixel group (PG1). The binning circuit 120 may read pixel signals of high-sensitivity pixels (H3_31, H3_33, H3_35) arranged in the first column line (CL1) of the pixel group (PG6). In this way, the binning circuit 120 may generate a left high-sensitivity binning signal (LHPS).

The binning circuit 120 may read pixel signals of high-sensitivity pixels (H2_14, H2_16, H2_18) arranged in the third column line (CL3) of the pixel group (PG3). The binning circuit 120 may read pixel signals of high-sensitivity pixels (H4_44, H4_46, H4_48) arranged in the third column line (CL3) of the pixel group (PG8). In this way, the binning circuit 120 may generate a right high-sensitivity binning signal (RHPS).

The binning circuit 120 may read pixel signals of low-sensitivity pixels (L1_1, L1_2, L1_3) arranged in the third column line (CL3) of the pixel group (PG1). The binning circuit 120 may read pixel signals of low-sensitivity pixels (L3_16, L3_17, L3_18) arranged in the third column line (CL3) of the pixel group (PG6). In this way, the binning circuit 120 may generate a right low-sensitivity binning signal (RLPS).

The binning circuit 120 may read pixel signals of the low-sensitivity pixels (L2_7, L2_8, L2_9) arranged in the first column line (CL1) of the pixel group (PG3). The binning circuit 120 may read pixel signals of the low-sensitivity pixels (L4_22, L4_23, L4_24) arranged in the first column line (CL1) of the pixel group (PG8) to generate a left low-sensitivity parallax image. In this way, the binning circuit 120 can generate a left low-sensitivity binning signal (LLPS).

It can be understood that the pixel signals of the high-sensitivity pixels and the pixel signals of the low-sensitivity pixels are read in the same manner in the remaining pixel groups (PG9,PG11,PG14,PG16) other than the pixel groups (PG1, PG3, PG6, PG8) of the pixel blocks (PXB1, PXB2).

The parallax image generator 130 may generate a left high-sensitivity parallax image by using the left high-sensitivity binning signal (LHPS) received from high-sensitivity pixels (H1_1, H1_3, H1_5, H3_31, H3_33, H3_35, H5_49, H5_51, H5_53, H7_79, H7_81, H7_83) of the pixel groups (PG1, PG6, PG9, PG14). For example, the parallax image generator 130 may generate a left high-sensitivity parallax image by using a first value obtained by summing pixel signals of high-sensitivity pixels (H1_1, H1_3, H1_5) of the pixel group (PG1), a second value obtained by summing pixel signals of high-sensitivity pixels (H3_31, H3_33, H3_35) of the pixel group (PG6), a third value obtained by summing pixel signals of high-sensitivity pixels (H5_49, H5_51, H5_53) of the pixel group (PG9), and a fourth value obtained by summing pixel signals of high-sensitivity pixels (H7_79, H7_81, H7_83) of the pixel group (PG14).

The parallax image generator 130 may generate a right low-sensitivity parallax image by using the right low-sensitivity binning signal (RLPS) received from low-sensitivity pixels (L1_1, L1_2, L1_3, L3_16, L3_17, L3_18, L5_25, L5_26, L5_27, L7_40, L7_41, L7_43) of the pixel groups (PG1, PG6, PG9, PG14). For example, the parallax image generator 130 may generate a right low-sensitivity parallax image by using a first value obtained by summing pixel signals of the low-sensitivity pixels (L1_1, L1_2, L1_3) of the pixel group (PG1), a second value obtained by summing pixel signals of the low-sensitivity pixels (L3_16, L3_17, L3_18) of the pixel group (PG6), a third value obtained by summing pixel signals of the low-sensitivity pixels (L5_25, L5_26, L5_27) of the pixel group (PG9), and a fourth value obtained by summing pixel signals of the low-sensitivity pixels (L7_40, L7_41, L7_42) of the pixel group (PG14).

It can be understood that the pixel signals of the high-sensitivity pixels and the pixel signals of the low-sensitivity pixels are read in the same manner in the remaining pixel blocks (PXB2, PXB4) other than the pixel blocks (PXB1, PXB3) so that the right high-sensitivity parallax image and the left low-sensitivity parallax image are generated.

As described above, the image sensing device according to the present embodiment may generate a left parallax image and a right parallax image by using pixels that have the same photosensitivity and are located opposite to each other in the first direction in adjacent pixel blocks.

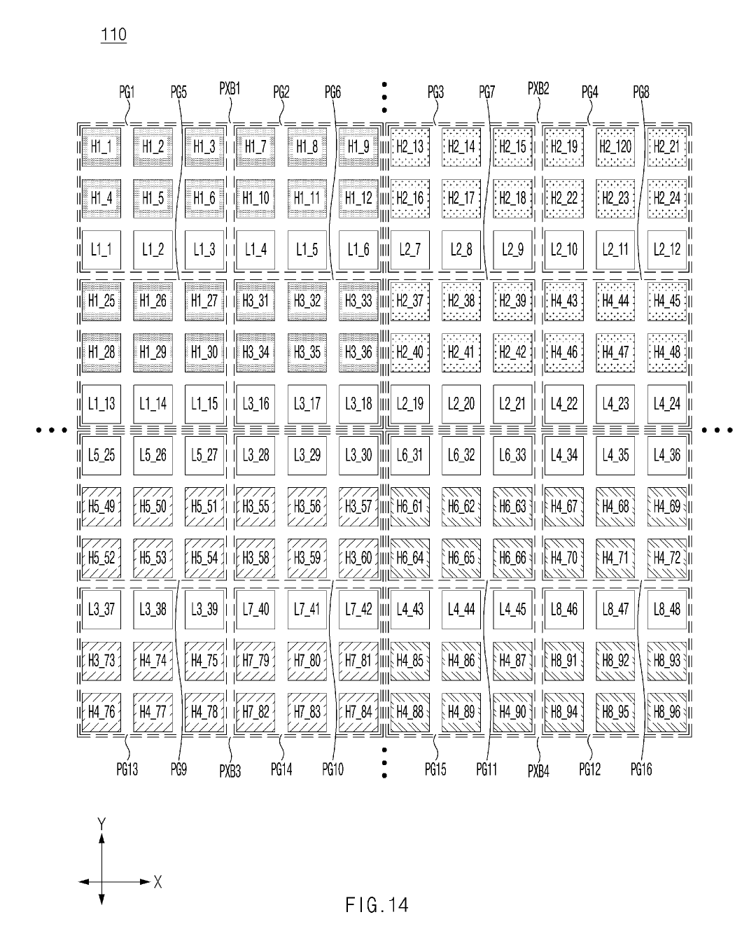

FIG. 14 is a diagram illustrating another embodiment of a structure in which pixel blocks are consecutively arranged in the pixel array of FIG. 2 based on some embodiments of the present disclosure. In the embodiment of FIG. 14, descriptions overlapping with those of FIG. 12 will herein be omitted, and as such, redundant descriptions thereof will herein be omitted for brevity.

Referring to FIG. 14, each pixel block (PXB1~PXB4) may include a plurality of pixel groups (PG1~PG16) arranged adjacent to each other. The plurality of pixel groups (PG1~PG16) may include high-sensitivity pixels (H1_1~H8_96) and low-sensitivity pixels (L1_1~L8_48) for generating an HDR image.

In each pixel group (PG1~PG8) of the pixel blocks (PXB1, PXB2), among the nine pixels arranged in a (3 × 3) matrix structure, six pixels arranged in a (3 × 2) matrix structure located at the upper side may be high-sensitivity pixels (H1_1~H1_6, H1_7~H1_12, H2_13~H2_18, H2_19~H2_24, H1_25~H1_30, H3_31~H3_36, H2_37~H2_42, H4_43~H4_48) and three pixels arranged in a (3 × 1) matrix structure located at the lower side may be low-sensitivity pixels (L1_1~L1_3, L1_4~L1_6, L2_7~L2_9, L2_10~L2_12, L1_13~L1_15, L3_16~L3_18, L2_19~L2_21, L4_22~L4_24).

On the other hand, in each pixel group (PG9~PG16) of the pixel block (PXB3, PXB4), among the nine pixels arranged in a (3 × 3) matrix structure, six pixels arranged in a (3 × 2) matrix structure located at the lower side may be high-sensitivity pixels (H5_49~H5_54, H3_55~H3_60, H6_61~H6_66, H4_67~H4_72, H3_73~H3_78, H7_79~H7_84, H4_85~H4_90, H8_91~H8_96) and three pixels arranged in a (3 × 1) matrix structure located at the upper side may be low-sensitivity pixels (L5_25~L5_27, L3_28~L3_30, L6_31~L6_33, L4_34~L4_36, L3_37~L3_39, L7_40~L7_42, L4_43~L4_45, L8_46~L8_48).

In the pixel blocks (PXB1, PXB2) adjacent to each other in the first direction, high-sensitivity pixels and low-sensitivity pixels may be arranged in the same pattern. In the pixel blocks (PXB3, PXB4) adjacent to each other in the first direction, high-sensitivity pixels and low-sensitivity pixels may be arranged in the same pattern. High-sensitivity pixels and low-sensitivity pixels of the pixel blocks (PXB1, PXB2) and the pixel blocks (PXB3, PXB4) may be located opposite to each other in the second direction. The high-sensitivity pixels or low-sensitivity pixels of the pixel blocks (PXB3, PXB4) may be used to generate parallax images in the second direction (e.g., vertical direction).

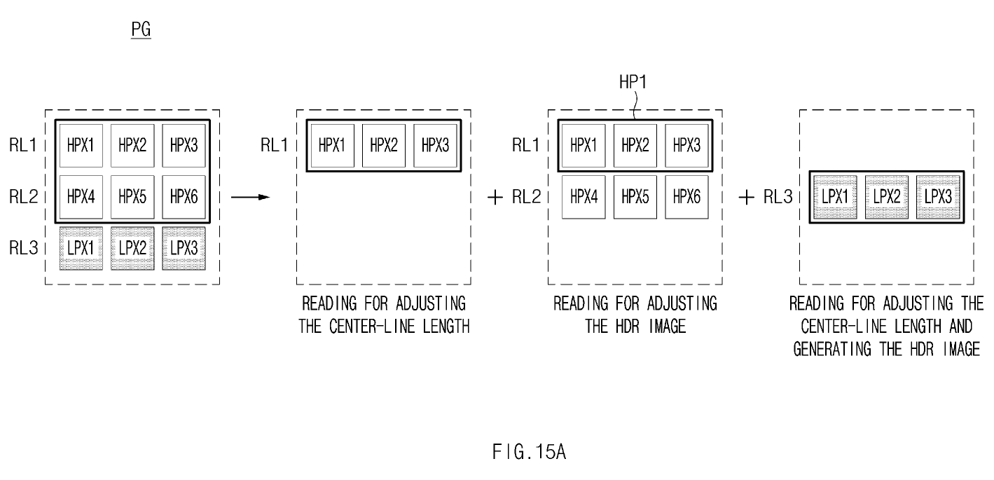

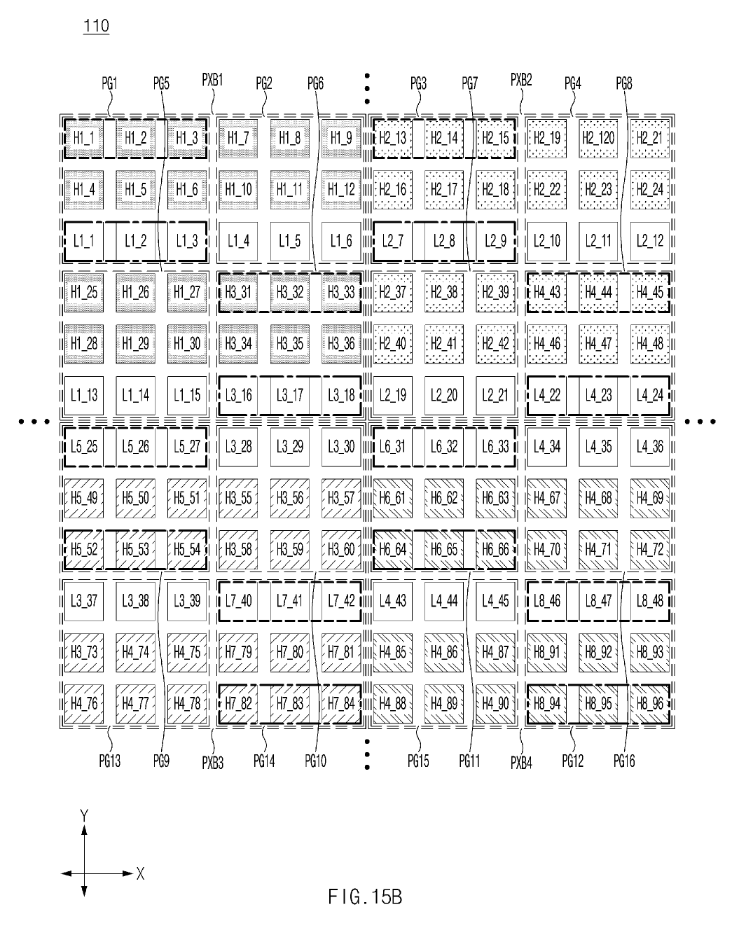

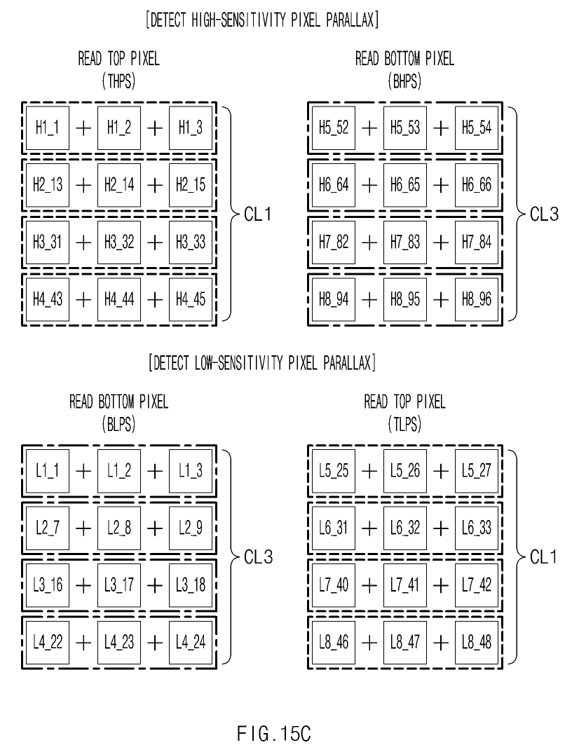

FIGS. 15A to 15C are diagrams showing a sixth embodiment of generating vertical parallax images and calculating a vertical parallax in the pixel array structure of FIG. 14 based on some embodiments of the present disclosure. In the embodiment of FIGS. 15A to 15C, descriptions overlapping with those of FIGS. 13A to 13C will herein be omitted, and as such, redundant descriptions thereof will herein be omitted for brevity.

Referring to FIG. 15A, the binning circuit 120 may generate a first binning image by binning pixel signals of three high-sensitivity pixels (HPX1, HPX2, HPX3) arranged in the first row line (RL1) among six high-sensitivity pixels (HPX1~HPX6). That is, the binning circuit 120 may generate a first binning image for adjusting the center-line length by binning pixel signals of three high-sensitivity pixels (HPX1, HPX2, HPX3) disposed in the first row line (RL1) different from the third row line (RL3) where the low-sensitivity pixels (LPX1~LPX3) are located. In addition, the binning circuit 120 may generate a second binning image for generating an HDR image by binning pixel signals of six pixels (HPX1~HPX6). In addition, the binning circuit 120 may generate a third binning image for adjusting the center-line length by binning pixel signals of three low-sensitivity pixels (LPX1~LPX3) disposed in the third row line (RL3).

A process for controlling the binning circuit 120 to perform binning of the pixel signal using the pixel array 110 illustrated in FIG. 14 will be described in more detail with reference to FIGS. 15B and 15C.

Referring to FIGS. 15B and 15C, the binning circuit 120 may read pixel signals of the pixel groups (PG1, PG3, PG6, PG8, PG9, PG11, PG14, PG16).

For example, the binning circuit 120 may read pixel signals of high-sensitivity pixels (H1_1, H1_2, H1_3) arranged in the first row line (RL1) of the pixel group (PG1). The binning circuit 120 may read pixel signals of high-sensitivity pixels (H2_13, H2_14, H2_15) arranged in the first row line (RL1) of the pixel group (PG3). In this way, the binning circuit 120 may generate a top high-sensitivity binning signal (THPS).

The binning circuit 120 may read pixel signals of high-sensitivity pixels (H5_52, H5_53, H5_54) arranged in the third row line (RL3) of the pixel group (PG9). The binning circuit 120 may read pixel signals of high-sensitivity pixels (H6_64, H6_65, H6_66) arranged in the third row line (RL3) of the pixel group (PG11). In this way, the binning circuit 120 may generate a bottom high-sensitivity binning signal (BHPS).

The binning circuit 120 may read pixel signals of low-sensitivity pixels (L1_1, L1_2, L1_3) arranged in the third row line (RL3) of the pixel group (PG1). The binning circuit 120 may read pixel signals of low-sensitivity pixels (L2_7, L2_8, L2_9) arranged in the third row line (RL3) of the pixel group (PG3). In this way, the binning circuit 120 may generate a bottom low-sensitivity binning signal (BLPS).

The binning circuit 120 may read pixel signals of low-sensitivity pixels (L5_25, L5_26, L5_27) arranged in the first row line (RL1) of the pixel group (PG9) to generate a top low-sensitivity parallax image. The binning circuit 120 may read pixel signals of the low-sensitivity pixels (L6_31, L6_32, L6_33) arranged in the first row line (RL1) of the pixel group (PG11) to generate a top low-sensitivity parallax image. In this way, the binning circuit 120 may generate a top low-sensitivity binning signal (TLPS).

It can be understood that the pixel signals of the high-sensitivity pixels and the pixel signals of the low-sensitivity pixels are read in the same manner in the remaining pixel groups other than the pixel groups (PG1, PG3, PG9, PG11).

The parallax image generator 130 may generate a top high-sensitivity parallax image by using the top high-sensitivity binning signal (THPS) received from high-sensitivity pixels (H1_1, H1_2, H1_3, H2_13, H2_14, H2_15, H3_31, H3_32, H3_33, H4_43, H4_44, H4_45) of the pixel groups (PG1, PG3, PG6, PG8). For example, the parallax image generator 130 may generate a top high-sensitivity parallax image by using a first value obtained by summing pixel signals of high-sensitivity pixels (H1_1, H1_2, H1_3) of the pixel group (PG1), a second value obtained by summing pixel signals of high-sensitivity pixels (H2_13, H2_14, H2_15) of the pixel group (PG3), a third value obtained by summing pixel signals of high-sensitivity pixels (H3_31, H3_32, H3_33) of the pixel group (PG6), and a fourth value obtained by summing pixel signals of high-sensitivity pixels (H4_43, H4_44, H4_45) of the pixel group (PG8).

The parallax image generator 130 may generate a bottom low-sensitivity parallax image by using the bottom low-sensitivity binning signal (BLPS) received from low-sensitivity pixels (L1_1, L1_2, L1_3, L2_7, L2_8, L2_9, L3_16, L3_17, L3_18, L4_22, L4_23, L4_24) of the pixel groups (PG1, PG3, PG6, PG8). For example, the parallax image generator 130 may generate a bottom low-sensitivity parallax image by using a first value obtained by summing pixel signals of low-sensitivity pixels (L1_1, L1_2, L1_3) of the pixel group (PG1), a second value obtained by summing pixel signals of low-sensitivity pixels (L2_7, L2_8, L2_9) of the pixel group (PG3), a third value obtained by summing pixel signals of low-sensitivity pixels (L3_16, L3_17, L3_18) of the pixel group (PG6), and a fourth value obtained by summing pixel signals of low-sensitivity pixels (L4_22, L4_23, L4_24) of the pixel group (PG8).

It can be understood that the pixel signals of the high-sensitivity pixels and the pixel signals of the low-sensitivity pixels are read in the same manner in the remaining pixel blocks (PXB2, PXB4) other than the pixel blocks (PXB1, PXB3) so that the right high-sensitivity parallax image and the left low-sensitivity parallax image are generated.

As described above, the image sensing device according to the present embodiment may generate a top parallax image and a bottom parallax image by using pixels that have the same photosensitivity and are located opposite to each other in the second direction in adjacent pixel blocks.

As is apparent from the above description, the image sensing device according to the embodiments of the present disclosure can improve autofocus accuracy by reducing the amount of parallax between the high-sensitivity image and the low-sensitivity image.

The embodiments of the present disclosure may provide a variety of advantageous effects capable of being directly or indirectly recognized by one of ordinary skill in the art.

Although a number of illustrative embodiments have been described, it should be understood that modifications and enhancements to the disclosed embodiments and other embodiments can be devised based on what is described and/or illustrated in the present disclosure. Therefore, the scope of the present disclosure should not be limited to the above-described embodiments but should include the equivalents thereof. Furthermore, the embodiments may be combined to form additional embodiments.

What is claimed is:

1. An image sensing device comprising:
a pixel group including a plurality of first pixels having a first photosensitivity and at least one second pixel having a second photosensitivity; and
a binning circuit configured to:
generate a first binning image by binning some first pixels among the plurality of first pixels;
generate a second binning image by binning the plurality of first pixels; and
generate a third binning image by binning the at least one second pixel.

2. The image sensing device according to claim 1, wherein the some first pixels are adjacent to each other in a first direction among the plurality of first pixels.

3. The image sensing device according to claim 1, wherein the some first pixels are adjacent to each other in a second direction among the plurality of first pixels.

4. The image sensing device according to claim 1, wherein
the at least one second pixel is arranged in the same direction as the some first pixels.

5. The image sensing device according to claim 1, wherein
the pixel group is configured to share one microlens.

6. The image sensing device according to claim 1, further comprising:
a parallax image generator configured to generate parallax images based on the first to third binning images.

7. An image sensing device comprising:
a first pixel;
a second pixel arranged adjacent to the first pixel in a first direction;
a third pixel arranged adjacent to the first pixel in a second direction;
a fourth pixel arranged adjacent to the third pixel in the first direction; and
a binning circuit configured to:
generate a first binning image by binning the first pixel and the third pixel;
generate a second binning image by binning the first pixel, the second pixel, and the third pixel; and
generate a third binning image by reading a pixel signal of the fourth pixel.

8. The image sensing device according to claim 7, wherein
the first to fourth pixels are configured to share one microlens.

9. The image sensing device according to claim 7, further comprising:
a parallax image generator configured to generate parallax images based on the first binning image, the second binning image, and the third binning image.

10. An image sensing device comprising:
a plurality of pixel blocks including a plurality of pixel groups arranged in a Bayer pattern, and arranged in a first direction and a second direction perpendicular to the first direction; and
a binning circuit configured to bin pixels included in each of the plurality of pixel groups,
wherein
each of the plurality of pixel groups includes a plurality of first pixels each having a first sensitivity and a plurality of second pixels each having a second sensitivity different from the first sensitivity;
the pixel blocks adjacent to each other in the first direction and the second direction are configured such that the first pixels and the second pixels are arranged in different patterns; and
the binning circuit outputs a first binning image by binning pixels disposed in one column line or one row line among the plurality of first pixels, outputs a second binning image by binning the plurality of first pixels, and outputs a third binning image by binning the second pixels.

11. The image sensing device according to claim 10, wherein
the first pixels and the second pixels are configured to share one microlens.

12. The image sensing device according to claim 10, further comprising:
a parallax image generator configured to generate parallax images based on the first binning image, the second binning image, and the third binning image.

13. An image sensing device comprising:
a first pixel block including a plurality of first pixel groups arranged in a Bayer pattern;
a second pixel block located adjacent to the first pixel block in a first direction and including a plurality of second pixel groups arranged in a Bayer pattern; and
a binning circuit configured to generate binning images by binning pixels of the first pixel block and the second pixel block,
wherein:
each of the plurality of first pixel groups includes a plurality of first pixels having a first photosensitivity and a second pixel having a second photosensitivity;
each of the plurality of second pixel groups includes a plurality of third pixels having the first photosensitivity and a fourth pixel having the second photosensitivity;
the plurality of first pixels and the plurality of third pixels are arranged symmetrically to each other in a specific direction; and
the second pixel and the fourth pixel are arranged symmetrically to each other in the specific direction.

14. The image sensing device according to claim 13, wherein the binning circuit is configured to:
generate a first binning image by binning some first pixels arranged adjacent to each other in the specific direction, among the plurality of first pixels;
generate a second binning image by binning some third pixels arranged adjacent to each other in the specific direction, among the plurality of third pixels;
generate a third binning image by reading a pixel signal of the second pixel; and
generate a fourth binning image by reading a pixel signal of the fourth pixel.

15. The image sensing device according to claim 14, further comprising:
a parallax image generator configured to generate parallax images based on the first to fourth binning images.

16. The image sensing device according to claim 15, wherein the parallax image generator is further configured to:
generate a first parallax image having the first photosensitivity based on the first binning image,
generate a second parallax image having the first photosensitivity based on the second binning image,
generate a third parallax image having the second photosensitivity based on the third binning image, and
generate a fourth parallax image having the second photosensitivity based on the fourth binning image.

17. An imaging device comprising:
an image sensing device including a plurality of first pixels having a first photosensitivity and at least one second pixel having a second photosensitivity, and configured to generate parallax images for a specific direction in response to binning images obtained by binning the plurality of first pixels and the at least one second pixel; and
a parallax calculator configured to compare the parallax images with each other to calculate parallax for the specific direction,
wherein the image sensing device is configured to:
generate a first binning image by binning some first pixels among the plurality of first pixels;
generate a second binning image by binning the plurality of first pixels; and
generate a third binning image by binning the at least one second pixel.

18. The imaging device according to claim 17, wherein the some first pixels are adjacent to each other in a first direction or a second direction among the plurality of first pixels.

19. The imaging device according to claim 17, wherein
the at least one second pixel is arranged in the same direction as the some first pixels.

20. The imaging device according to claim 17, wherein
the plurality of first pixels and the second pixel are configured to share one microlens.
